(19) United States
(12) Patent Application Publication
(10) Pub. No.: US 2025/0237763 A1
(43) Pub. Date: Jul. 24, 2025

(54) DISTANCE MEASURING DEVICE

(71) Applicant: SONY SEMICONDUCTOR SOLUTIONS CORPORATION, Kanagawa (JP)

(72) Inventors: Yoshiki EBIKO, Kanagawa (JP); Kyohei MIZUTA, Kanagawa (JP); Yutaro KOMURO, Kanagawa (JP); Yohtaro YASU, Kanagawa (JP); Sousuke NARISAWA, Kanagawa (JP); Sozo YOKOGAWA, Kanagawa (JP); Atsushi TODA, Kanagawa (JP); Kazuhiro GOI, Kanagawa (JP)

(73) Assignee: SONY SEMICONDUCTOR SOLUTIONS CORPORATION, Kanagawa (JP)

(21) Appl. No.: 18/698,487

(22) PCT Filed: Jul. 26, 2022
(86) PCT No.: PCT/JP2022/028679

§ 371 Date: Apr. 4, 2024

(30) Foreign Application Priority Data
Oct. 13, 2021 (JP) 2021-168293

(51) Int. Cl. G01S 17/34; G01S 7/481; G01S 7/4911; G01S 7/4912; G01S 7/4913; G01S 17/931; H01L 23/498; H01L 25/16

(52) U.S. Cl. CPC G01S 17/34; G01S 7/4911; G01S 7/4913; G01S 7/4917; H01L 23/49827; H01L 25/167; G01S 7/4818; G01S 17/931

(57) ABSTRACT

A distance measuring device according to an embodiment of the present disclosure comprises a first substrate including a first optical waveguide configured to convey a chirp signal, a splitter configured to split the chirp signal into a transmission signal and a reference signal, and a coupler and detector block configured to output a beat signal based on the reference signal and a reflected signal. The distance measure device comprises a second substrate stacked on the first substrate and including a converter configured to output a digital beat signal based on the beat signal; and a controller configured to output an electronic control signal that controls generation of the chirp signal.

### CROSS REFERENCE TO RELATED APPLICATIONS

This application claims the benefit of Japanese Priority Patent Application JP 2021-168293 filed on Nov. 9, 2021, the entire contents of which are incorporated herein by reference.

### TECHNICAL FIELD

The present disclosure relates to a distance measuring device.

### BACKGROUND ART

There has been developed a light detection and ranging (LiDAR) system using a photonic integration circuit (PIC) in which in place of an optical fiber, an optical component such as a silicon (Si) waveguide is stacked on a silicon-on-insulator (SOI) substrate (for example, refer to PTL 1).

### CITATION LIST

### Patent Literature

PTL 1: U.S. Unexamined Patent Application Publication No. 2021/0109195

### SUMMARY

### Technical Problem

Such a system is desired to be further downsized. It is therefore desirable to provide a distance measuring device that is capable of being downsized.

A distance measuring device according to an embodiment of the present disclosure comprises a first substrate including a first optical waveguide configured to convey a chirp signal, a splitter configured to split the chirp signal into a transmission signal and a reference signal, and a coupler and detector block configured to output a beat signal based on the reference signal and a reflected signal. The distance measure device comprises a second substrate stacked on the first substrate and including a converter configured to output a digital beat signal based on the beat signal; and a controller configured to output an electronic control signal that controls generation of the chirp signal. A distance measuring device according to another embodiment of the present disclosure comprises a first substrate comprising one or more optical circuits that output a transmission signal to an object and that receives a reflected signal from the object, and a second substrate bonded to the first substrate and comprising one or more electronic circuits that control generation of the transmission signal and that process the reflected signal. A system according to an embodiment of the present disclosure comprises an object, and a distance measuring device that measures a distance to the object. The distance measuring device may include a first substrate including a first optical waveguide configured to convey a chirp signal, a splitter configured to split the chirp signal into a transmission signal and a reference signal, and a coupler and detector block configured to output a beat signal based on the reference signal and a reflected signal. The distance measuring device includes a second substrate stacked on the first substrate and including a converter configured to output a digital beat signal based on the beat signal, and a controller configured to output an electronic control signal that controls generation of the chirp signal. A distance measuring device according to an embodiment of the present disclosure includes a photonic integration circuit substrate and a signal processing substrate. The photonic integration circuit substrate includes a first waveguide, a splitter, a second waveguide, and a signal generator that are provided in a common silicon layer. The first waveguide transmits a chirp signal. The splitter splits the chirp signal into a transmission signal and a reference signal. The second waveguide transmits a return signal corresponding to a signal having a delayed phase in relation with the transmission signal. The signal generator generates a beat signal on the basis of the reference signal and the return signal. The signal processing substrate includes a converter and a signal processor. The converter performs analog-to-digital conversion of the beat signal. The signal processor processes the beat signal being digital generated by the converter. The photonic integration circuit substrate and the signal processing substrate are stacked on each other, and are electrically coupled to each other through a joining surface between the photonic integration circuit substrate and the signal processing substrate.

In the distance measuring device according to the embodiment of the present disclosure, in the photonic integration circuit substrate, the first waveguide, the splitter, the second waveguide, and the signal generator are provided in the common silicon layer. In addition, the converter and the signal processor are provided in the signal processing substrate. Furthermore, the photonic integration circuit substrate and the signal processing substrate are stacked on each other, and are electrically coupled to each other through the joining surface between the photonic integration circuit substrate and the signal processing substrate. This allows for downsizing, as compared with a module in which a plurality of RF components is coupled through an optical fiber.

### BRIEF DESCRIPTION OF DRAWINGS

The accompanying drawings are included to provide a further understanding of the technology, and are incorporated in and constitute a part of this specification. The drawings show illustrative embodiments and, together with the specification, serve to explain various principles of the technology.

FIG. 1 is a diagram illustrating a schematic configuration example of a distance measuring device according to a first embodiment of the present disclosure.

FIG. 2 is a diagram illustrating a cross-sectional configuration example of the distance measuring device in FIG. 1.

FIG. 3 is a diagram illustrating a schematic configuration example of an antenna in FIG. 1.

FIG. 4 is a diagram illustrating a cross-sectional configuration example of a Si antenna taken along an A-A line in FIG. 3.

FIG. 5 is a diagram illustrating a cross-sectional configuration example of the Si antenna taken along a B-B line in FIG. 3.

FIG. 6 is a diagram illustrating a schematic configuration example of a detector in FIG. 1.

FIG. 7 is a diagram illustrating a perspective configuration example of the detector in FIG. 6.

FIG. 8A is a cross-sectional view for describing a method of manufacturing the distance measuring device in FIG. 1.

FIG. 8B is a cross-sectional view for describing a manufacturing method subsequent to FIG. 8A.

FIG. 8C is a cross-sectional view for describing a manufacturing method subsequent to FIG. 8B.

FIG. 8D is a cross-sectional view for describing a manufacturing method subsequent to FIG. 8C.

FIG. 8E is a cross-sectional view for describing a manufacturing method subsequent to FIG. 8D.

FIG. 8F is a cross-sectional view for describing a manufacturing method subsequent to FIG. 8E.

FIG. 8G is a cross-sectional view for describing a manufacturing method subsequent to FIG. 8F.

FIG. 9 is a diagram illustrating a schematic configuration example of a distance measuring device according to a second embodiment of the present disclosure.

FIG. 10 is a diagram illustrating a cross-sectional configuration example of the distance measuring device in FIG. 9.

FIG. 11 is a diagram illustrating a planar configuration example of a Ge-PD in the distance measuring device in FIG. 9.

FIG. 12A is a cross-sectional view for describing a method of manufacturing the distance measuring device in FIG. 9.

FIG. 12B is a cross-sectional view for describing a manufacturing method subsequent to FIG. 12A.

FIG. 12C is a cross-sectional view for describing a manufacturing method subsequent to FIG. 12B.

FIG. 12D is a cross-sectional view for describing a manufacturing method subsequent to FIG. 12C.

FIG. 12E is a cross-sectional view for describing a manufacturing method subsequent to FIG. 12D.

FIG. 12F is a cross-sectional view for describing a manufacturing method subsequent to FIG. 12E.

FIG. 12G is a cross-sectional view for describing a manufacturing method subsequent to FIG. 12F.

FIG. 13 is a diagram illustrating a schematic configuration example of a distance measuring device according to a third embodiment of the present disclosure.

FIG. 14 is a diagram illustrating a cross-sectional configuration example of the distance measuring device in FIG. 13.

FIG. 15 is a diagram illustrating a modification example of a cross-sectional configuration of the distance measuring device in FIG. 13.

FIG. 16 is a diagram illustrating a modification example of a cross-sectional configuration of the distance measuring device in FIG. 13.

FIG. 17 is a diagram illustrating a modification example of a cross-sectional configuration of the distance measuring device in FIG. 13.

FIG. 18 is a diagram illustrating a schematic configuration example of a distance measuring device according to a fourth embodiment of the present disclosure.

FIG. 19 is a diagram illustrating a cross-sectional configuration example of the distance measuring device in FIG. 18.

FIG. 20A is a cross-sectional view for describing a method of manufacturing the distance measuring device in FIG. 18.

FIG. 20B is a cross-sectional view for describing a manufacturing method subsequent to FIG. 20A.

FIG. 20C is a cross-sectional view for describing a manufacturing method subsequent to FIG. 20B.

FIG. 20D is a cross-sectional view for describing a manufacturing method subsequent to FIG. 20C.

FIG. 20E is a cross-sectional view for describing a manufacturing method subsequent to FIG. 20D.

FIG. 20F is a cross-sectional view for describing a manufacturing method subsequent to FIG. 20E.

FIG. 21 is a diagram illustrating a modification example of a cross-sectional configuration of the distance measuring device according to any of the embodiments and modification examples thereof.

FIG. 22 is a diagram illustrating a modification example of a cross-sectional configuration of the distance measuring device according to any of the embodiments and modification examples thereof.

FIG. 23 is a diagram illustrating a modification example of a cross-sectional configuration of the distance measuring device according to any of the embodiments and modification examples thereof.

FIG. 24 is a diagram illustrating a modification example of a cross-sectional configuration of the distance measuring device according to any of the embodiments and modification examples thereof.

FIG. 25 is a diagram illustrating a modification example of a cross-sectional configuration of the distance measuring device according to any of the embodiments and modification examples thereof.

FIG. 26 is a diagram illustrating a modification example of a cross-sectional configuration of the distance measuring device according to any of the embodiments and modification examples thereof.

FIG. 27 is a diagram illustrating a modification example of a cross-sectional configuration of the distance measuring device according to any of the embodiments and modification examples thereof.

FIG. 28 is a diagram illustrating a modification example of a cross-sectional configuration of the distance measuring device according to any of the embodiments and modification examples thereof.

FIG. 29 is a diagram illustrating a modification example of a cross-sectional configuration of the distance measuring device according to any of the embodiments and modification examples thereof.

FIG. 30A is a cross-sectional view for describing a method of manufacturing the distance measuring device in FIG. 29.

FIG. 30B is a cross-sectional view for describing a manufacturing method subsequent to FIG. 30A.

FIG. 30C is a cross-sectional view for describing a manufacturing method subsequent to FIG. 30B.

FIG. 30D is a cross-sectional view for describing a manufacturing method subsequent to FIG. 30C.

FIG. 31 is a diagram illustrating a modification example of a cross-sectional configuration of the distance measuring device according to any of the embodiments and modification examples thereof.

FIG. 32 is a diagram illustrating a modification example of a cross-sectional configuration of the distance measuring device according to any of the embodiments and modification examples thereof.

FIG. 33A is a cross-sectional view for describing a method of manufacturing the distance measuring device in FIG. 32.

FIG. 33B is a cross-sectional view for describing a manufacturing method subsequent to FIG. 33A.

FIG. 33C is a cross-sectional view for describing a manufacturing method subsequent to FIG. 33B.

FIG. 33D is a cross-sectional view for describing a manufacturing method subsequent to FIG. 33C.

FIG. 33E is a cross-sectional view for describing a manufacturing method subsequent to FIG. 33D.

FIG. 33F is a cross-sectional view for describing a manufacturing method subsequent to FIG. 33E.

FIG. 33G is a cross-sectional view for describing a manufacturing method subsequent to FIG. 33F.

FIG. 33H is a cross-sectional view for describing a manufacturing method subsequent to FIG. 33G.

FIG. 33I is a cross-sectional view for describing a manufacturing method subsequent to FIG. 33H.

FIG. 34 is a diagram illustrating a modification example of a cross-sectional configuration of the distance measuring device according to any of the embodiments and modification examples thereof.

FIG. 35 is a diagram illustrating a modification example of a cross-sectional configuration of the distance measuring device according to any of the embodiments and modification examples thereof.

FIG. 36 is a diagram illustrating a modification example of a cross-sectional configuration of the distance measuring device according to any of the embodiments and modification examples thereof.

FIG. 37 is a diagram illustrating a modification example of a cross-sectional configuration of the distance measuring device according to any of the embodiments and modification examples thereof.

FIG. 38 is a diagram illustrating a modification example of a cross-sectional configuration of the distance measuring device according to any of the embodiments and modification examples thereof.

FIG. 39 is a block diagram depicting an example of schematic configuration of a vehicle control system.

FIG. 40 is a diagram of assistance in explaining an example of installation positions of an outside-vehicle information detecting section and an imaging section.

### DESCRIPTION OF EMBODIMENTS

In the following, description is given of embodiments of the present disclosure in detail with reference to the drawings. It is to be noted that the description is given in the following order.

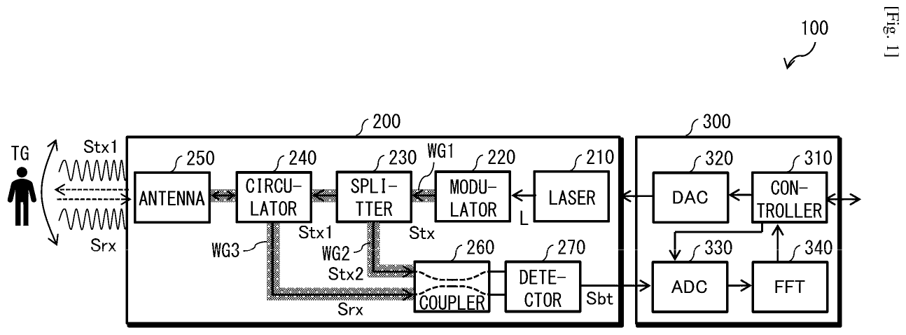

### 1. First Embodiment (FIGS. 1 to 8G)

An example in which a PIC substrate and a signal processing substrate are stacked by Cu—Cu coupling

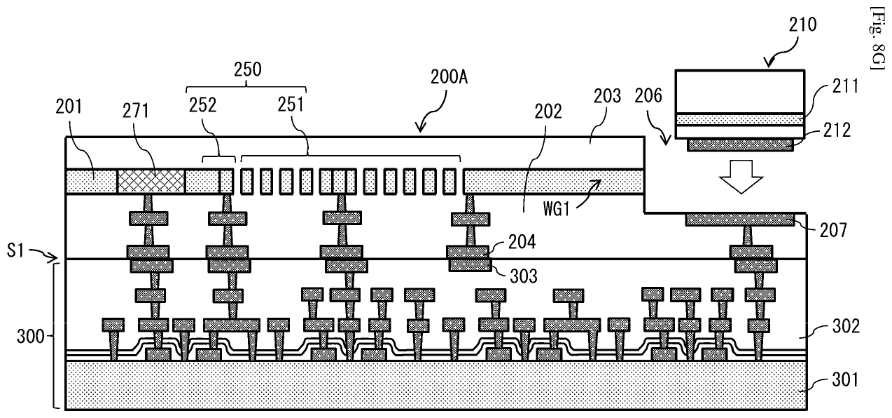

### 2. Second Embodiment (FIGS. 9 to 12G)

An example in which a PIC substrate and a signal processing substrate are stacked by TCV coupling

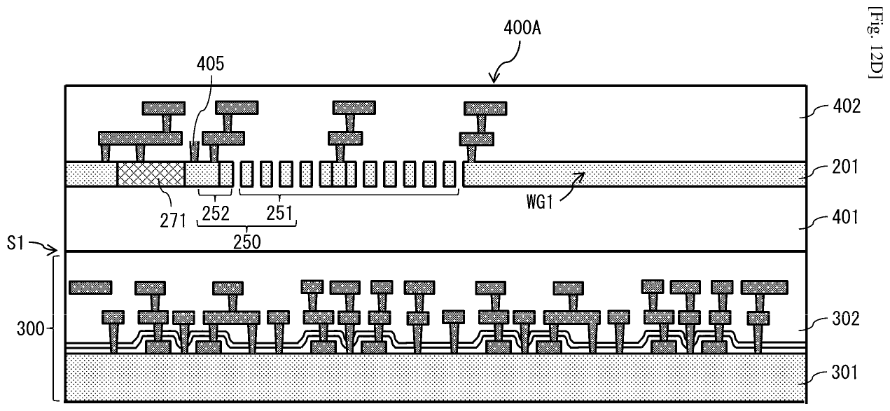

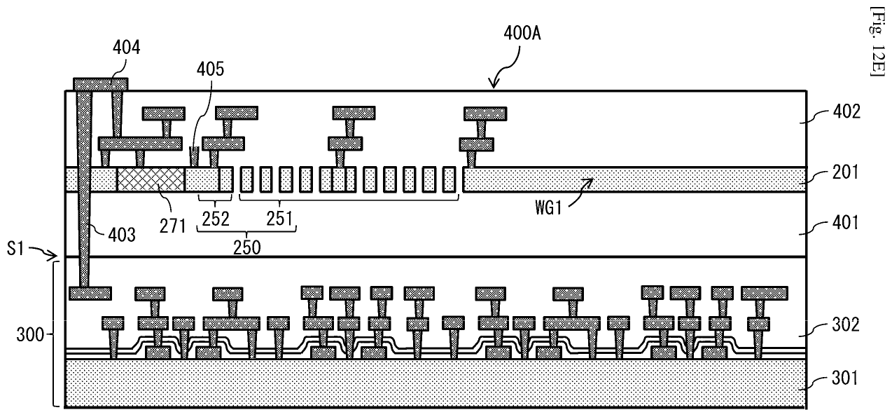

### 3. Third Embodiment (FIGS. 13 and 14)

An example in which a PIC substrate and a signal processing substrate are stacked by chip-on-wafer (CoW) coupling

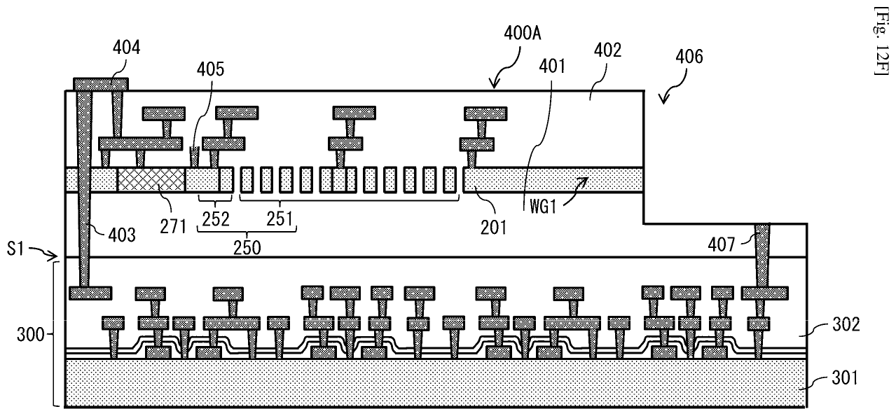

### 4. Modification Examples of Third Embodiment (FIGS. 15 to 17)

### Variations of Alignment

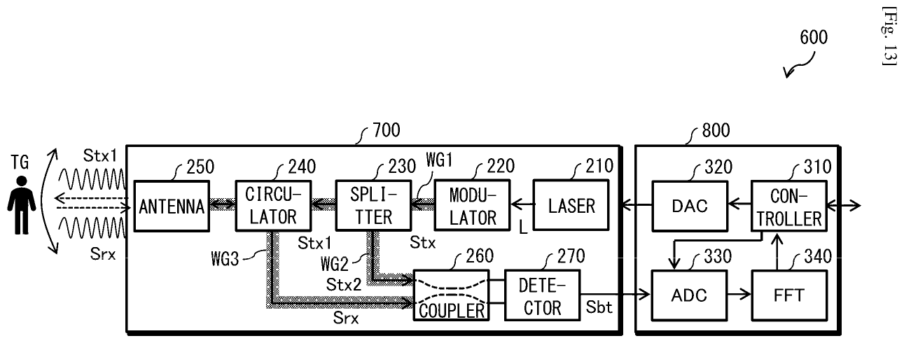

### 5. Fourth Embodiment (FIGS. 18 to 20F)

An example in which a PIC layer is bonded onto a signal processing substrate

### 6. Modification Example of Fourth Embodiment (FIG. 21)

An example in which an STI is provided directly below a Si antenna

### 7. Modification Examples of Embodiments

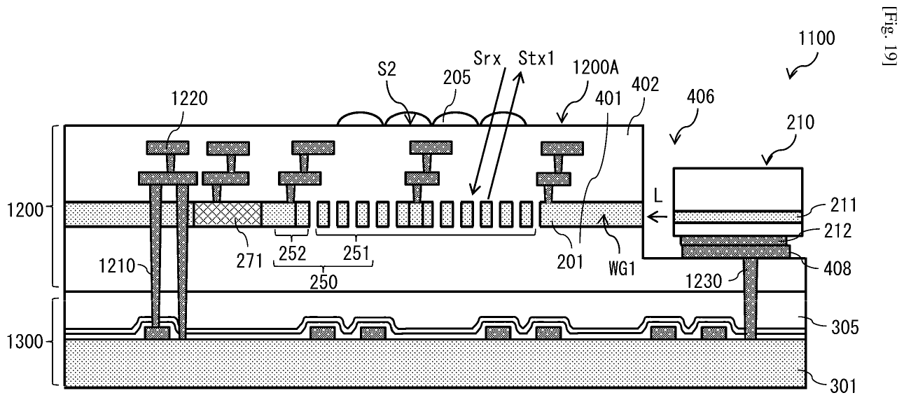

Modification Example A: An example in which a tapered section is provided at an entrance end of an optical waveguide (FIGS. 22 to 24)

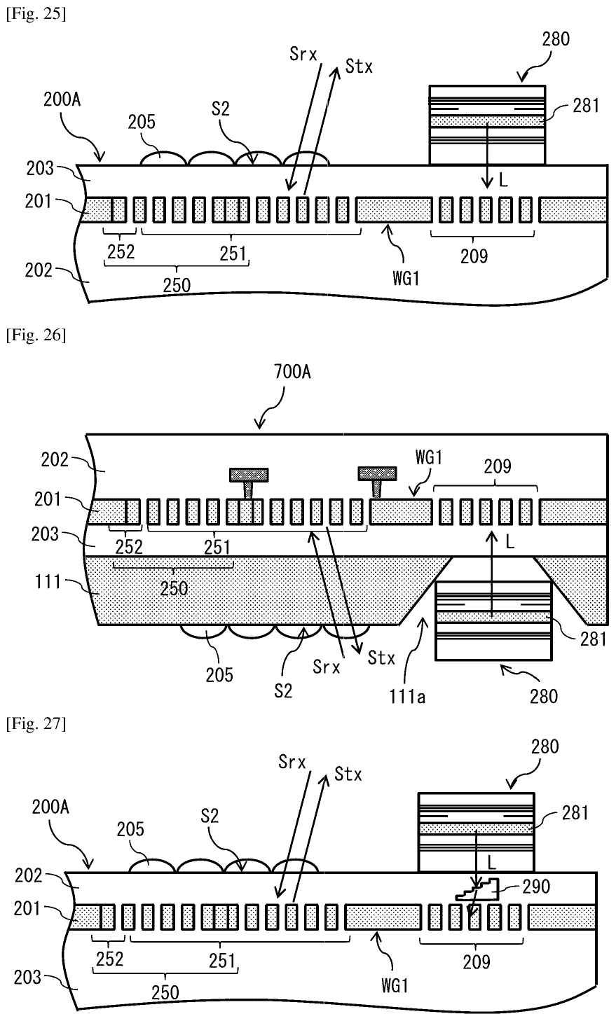

Modification Example B: An example in which a surface emitting laser is used as a laser (FIGS. 25 to 28)

Modification Example C: An example in which a gap is provided directly above and directly below a Si antenna (FIGS. 29 to 31)

Modification Example D: An example in which a gap is provided directly below a Si antenna (FIGS. 32 to 34)

Modification Example E: An example in which a reflection layer is provided directly below a Si antenna (FIG. 35)

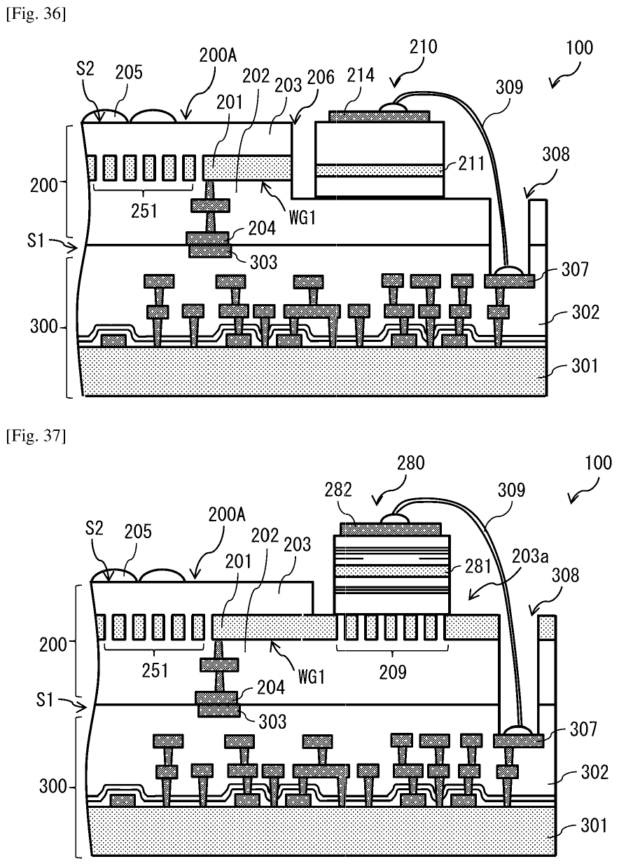

Modification Example F: An example in which a laser and a signal processing substrate are coupled to each other by a bonding wire (FIGS. 36 to 38)

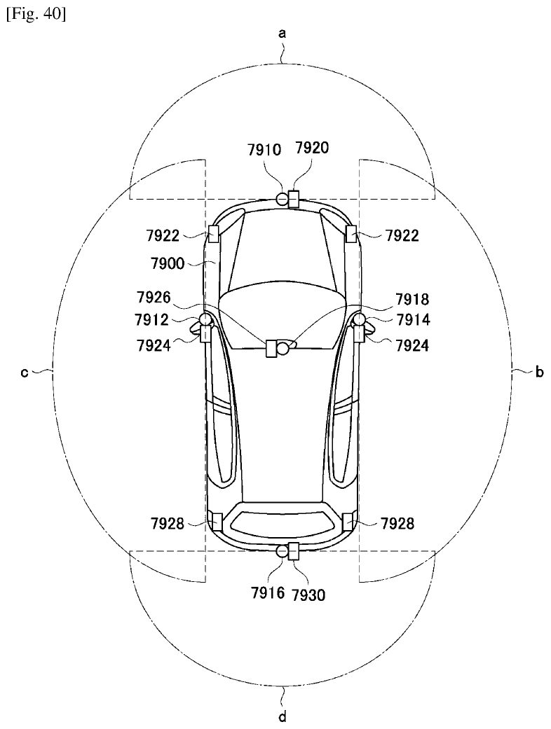

### 8. Application Example (FIGS. 39 and 40)

### 1. First Embodiment

### Configuration

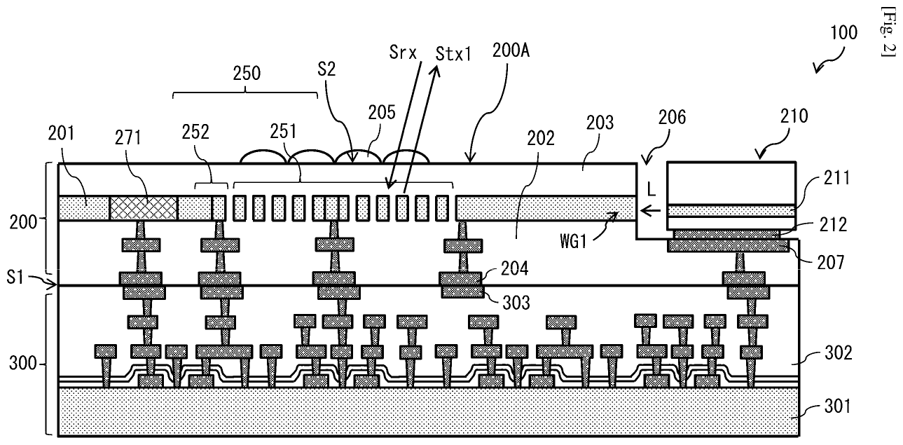

FIG. 1 illustrates a schematic configuration example of a distance measuring device 100 according to a first embodiment of the present disclosure. FIG. 2 illustrates a cross-sectional configuration example of the distance measuring device 100. The distance measuring device 100 includes a frequency modulated continuous wave (FMCW) LiDAR. In the FMCW LiDAR, laser light (transmission signal) of which a frequency has been modulated to be linearly increased is continuously applied to determine a distance by a frequency difference between the transmission signal and reflected light (return signal).

The distance measuring device 100 includes, for example, an upper die 200 and a lower die 300, as illustrated in FIG. 1. For example, as illustrated in FIG. 2, the upper die 200 and the lower die 300 are stacked on each other, and are electrically coupled to each other through a joining surface S1 between the upper die 200 and the lower die 300. Throughout the instant description, the terms “die,” “chip,” and/or like terms may be used interchangeable and/or may be referred to as a substrate.

### (Upper Die 200)

The upper die 200 includes, for example, a laser 210, a modulator 220, a splitter 230, a circulator 240, an antenna 250, a coupler 260, and a detector 270, as illustrated in FIG. 1. In the upper die 200, the modulator 220, the splitter 230, the circulator 240, the antenna 250, the coupler 260, and the detector 270 are provided in a photonic integration circuit (PIC) substrate 200A. A combination of the coupler 260 and the detector 270 may be referred to as a couple and detector block that, for example, outputs a beat signal Sbt.

The laser 210 includes a light source chip that generates a light signal. Examples of the laser 210 include a chip-shaped edge emitting semiconductor laser, and the laser 210 emits laser light L having a predetermined fixed wavelength (e.g., 1550 nm) from an end surface of an active layer 211 in accordance with control by a controller 310. The laser 210 is mounted on the PIC substrate 200A to cause the laser light L to enter an end surface (optical waveguide WG1 to be described later) of the PIC substrate 200A. The laser 210 is mounted on the PIC substrate 200A to set a light spot (light spot generated on the end surface of the active layer 211) of the laser 210 at the same height as the Si layer 201 (optical waveguide WG1). The PIC substrate 200A has a cutout section 206, and the laser 210 is mounted on a coupling pad 207 provided on a bottom surface of the cutout section 206. An electrode of the laser 210 and the coupling pad 207 each include, for example, copper (Cu), and are joined to each other with a bump 212 including Cu interposed therebetween.

The PIC substrate 200A includes, for example, a Si layer 201, and an interlayer insulating film 202 and a buried oxide (BOX) layer 203, as illustrated in FIG. 2. The Si layer 201 is sandwiched between the interlayer insulating film 202 and the BOX layer 203. The BOX layer 203 and the Si layer 201 are obtained by removing a Si substrate 111 to be described later from a silicon-on-insulator (SOT) substrate 110 to be described later. The BOX layer 203 includes a SiO₂ layer. The interlayer insulating film 202 is a layer provided on the SOI substrate 110, and has a configuration in which a plurality of patterned wiring layers and a via that couples the wiring layers to each other are provided in a plurality of SiO₂ layers stacked. A front surface of the interlayer insulating film 202 serves as a bottom surface of the upper die 200. The front surface of the interlayer insulating film 202 is in contact with an upper surface of the lower die 300 (interlayer insulating film 302 to be described later). A coupling pad 204 including Cu is exposed on the front surface of the interlayer insulating film 202. In contrast, a coupling pad 303 including Cu is exposed on the upper surface of the lower die 300 (interlayer insulating film 302 to be described later). The coupling pad 204 and the coupling pad 303 are joined to each other. This causes the PIC substrate 200A and the lower die 300 to be joined to each other on the bottom surface of the upper die 200 and the upper surface of the lower die 300. In FIG. 2, a joining surface between the bottom surface of the upper die 200 and the upper surface of the lower die 300 (interlayer insulating film 302 to be described later) is expressed as SL. The front surface of the BOX layer 203 serves as the upper surface of the upper die 200, and serves as an entrance/exit surface S2. As may be appreciated, the Cu—Cu bond between dies 200 and 300 using coupling pads 204 and 303 does not require a wiring layer between the antenna 251 and the entrance/exit surface S2, where the existence of such a wiring layer may cause loss of light transmitted and/or received by the antenna 251. Accordingly, the Cu—Cu bond between dies 200 and 300 in FIG. 2 enables improved light transmission and/or reception.

Optical waveguides WG1, WG2, and WG3 are provided in the Si layer 201. The optical waveguide WG1 extends from an end surface of the PIC substrate 200A to the antenna 250 via the modulator 220, the splitter 230, and the circulator 240. The optical waveguide WG2 is an optical wavelength branching from the optical waveguide WG1 in the splitter 230, and is coupled to one input end (optical waveguide 261 to be described later) of the coupler 260. The optical waveguide WG3 is an optical waveguide branching from the optical waveguide WG1 in the circulator 240, and is coupled to another input end (optical waveguide 262 to be described later) of the coupler 260.

The laser light L emitted from the laser 210 enters the optical waveguide WG1. The laser light L propagating through the optical waveguide WG1 is inputted to the modulator 220. The modulator 220 performs frequency modulation of the laser light L in accordance with control by the controller 310. For example, the modulator 220 modulates the laser light L to linearly increase a frequency of the laser light L with a lapse of time, and thereafter modulates the laser light L to linearly decrease the frequency of the laser light L with a lapse of time. For example, the modulator 220 pe-riodically repeats such linear increase and decrease of the frequency to generate a transmission signal Stx, and outputs the transmission signal Stx to the splitter 230 through the optical waveguide WG1. The transmission signal Stx is a chirp signal obtained by performing frequency modulation of the laser light L by the modulator 220. The modulator 220 is provided in the Si layer 201, for example. The modulator 220 includes, for example, a Mach-Zehnder interferometer in which a Si waveguide branches into two. On this occasion, the modulator 220 generates a signal having a changed phase of light by forming a PN junction in one branching waveguide and applying a voltage of an alternating current waveform to the PN junction to change a refractive index by carrier plasma effect. The modulator 220 is able to modulate the phase of an original signal by multiplexing a generated signal waveform and an original waveform at an exit of the interferometer.

The splitter 230 splits the transmission signal Stx into a transmission signal Stx (transmission signal Stx1) for being applied to a target TG, and a transmission signal Stx (transmission signal Stx2) for interfering with a return signal Srx in the coupler 260. The transmission signal Stx1 has most of energy of the transmission signal Stx. The transmission signal Stx2 is a reference signal having an amount of energy that is much smaller than the energy of the transmission signal Stx1, but sufficient to interfere with the return signal Srx in the coupler 260. The return signal Srx corresponds to a signal having a delayed phase in relation to the transmission signal Stx1. The return signal Srx is generated by reflecting the transmission signal Stx by the target TG.

The splitter 230 is an element having three ports. In the splitter 230, a first port and a third port are present in the optical waveguide WG1. A second port is present in the optical waveguide WG2. The optical waveguide WG2 is disposed in proximity to a portion between the first port and the third port. This causes the light signal that propagates through the optical waveguide WG1 to leak into the optical waveguide WG2. The light signal having leaked from the optical waveguide WG1 to the optical waveguide WG2 propagates through the optical waveguide WG2 as the transmission signal Stx2.

The circulator 240 is an element having three ports. In the circulator 240, the transmission signal Stx1 having entered from a first port is transmitted to a third port, and the return signal Srx having entered from the third port is transmitted to a second port. In the circulator 240, the optical waveguide WG1 is coupled to the first port, and the optical waveguide WG2 is coupled to the second port. An optical waveguide extending from the antenna 250 is coupled to the third port. For example, the circulator 240 serves to rectify a light signal to be transmitted and a light signal received from a Si antenna 251. In the circulator 240, signal intensity of each of a transmission signal and a reception signal is divided into 50% and 50% at each branch by a configuration in which an optical waveguide including Si branches. Handling such half signals makes it possible to divide transmission light and reception light.

The antenna 250 is a non-mechanical scanner not having a driving section. The antenna 250 transmits the transmission signal Stx1 to the target TG through a lens 205, and receives the return signal Srx through the lens 205. The lens 205 is bonded to a region (entrance/exit surface S2) opposed to the Si antenna 251 of a front surface of the PIC substrate 200A. The transmission signal Stx1 is outputted from the entrance/exit surface S2, and the return signal Srx enters the entrance/exit surface S2. The lens 205 is bonded to the entrance/exit surface S2, and the transmission signal Stx is outputted from the antenna 250 to outside through the lens 205 and the entrance/exit surface S2, and the return signal Srx enters the antenna 250 from the outside through the lens 205 and the entrance/exit surface S2.

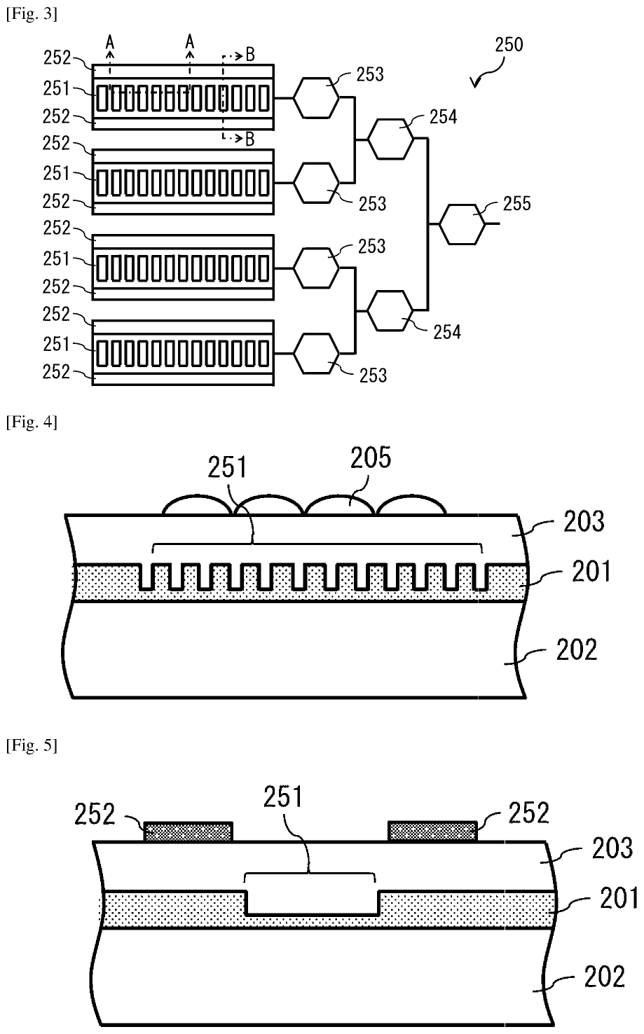

The antenna 250 includes, for example, a plurality (e.g., four) of antenna bodies each including the Si antenna 251 and a pair of heaters 252 provided on both sides of the Si antenna 251, as illustrated in FIG. 3. The antenna bodies each extend in a common direction, and the plurality of antenna bodies are disposed side by side at predetermined intervals in a direction orthogonal to the direction where the antenna bodies extend.

The Si antenna 251 includes a diffraction grating provided in the Si layer 201. The diffraction grating is, for example, an element in which a plurality of grooves or through holes is disposed side by side in one line with a pitch of several hundreds of nm in the Si layer 201. The Si antenna 251 outputs the transmission signal Stx1, which has a peak at a certain location corresponding to the pitch of the diffraction grating, to a front surface of the Si layer 201 at a predetermined angle in accordance with control by the controller 310. The heaters 252 each include a resistor element extending along the Si antenna 251. The heaters 252 each heat the Si antenna 251 by heat generation of the resistor element caused by application of a current to the resistor element in accordance with control by the controller 310. In the Si antenna 251, a refractive index is changed by heating by the heaters 252, and the transmission signal Stx1 is outputted at an angle corresponding to change in the refractive index. That is, the Si antenna 251 sweeps the transmission signal Stx1 in a predetermined external region in accordance with control by the controller 310.

In a case where the antenna 250 includes four antenna bodies, the antenna 250 further includes, for example, four optical switches 253 that are provided one for each of the antenna bodies, and two optical switches 254 that are provided one for every two optical switches 253, as illustrated in FIG. 3. Each of the optical switches 253 is a switch that connects and disconnects an optical waveguide between two terminals (a first terminal and a second terminal). Each of the optical switches 254 is a switch that connects and disconnects an optical waveguide between two terminals (a third terminal and a fourth terminal). The antenna 250 further includes, for example, one optical switch 255 coupled to the two optical switches 254, as illustrated in FIG. 3. The optical switch 255 is a switch that connects and disconnects an optical waveguide between two terminals (a fifth terminal and a sixth terminal).

In each of the optical switches 253, the first terminal is coupled to the antenna body, and a second terminal is coupled to the second terminal of another optical switch 253 and the third terminal of the optical switch 254. In each of the optical switches 254, the third terminal is coupled to the second terminals of two corresponding optical switches 253, and the fourth terminal is coupled to the fourth terminal of the other optical switch 254 and the fifth terminal of the optical switch 255. In the optical switch 255, the fifth terminal is coupled to the fourth terminals of the two optical switches 254, and the sixth terminal is coupled to the second port of the circulator 240.

The antenna bodies each include, for example, a diffraction grating provided in the Si layer 201, as illustrated in FIGS. 4 and 5. FIG. 4 illustrates a cross-sectional configuration example of the antenna body taken along a line A-A in FIG. 3. FIG. 5 illustrates a cross-sectional configuration example of the antenna body taken along a line B-B in FIG. 3. The diffraction grating is, for example, an element in which a plurality of grooves is disposed side by side in one line with a pitch of several hundreds of nm in the Si layer 201, as illustrated in FIGS. 4 and 5. The depth of each of the grooves is, for example, several hundreds of nm, and the thickness of a portion, corresponding to a base of the diffraction grating, of the Si layer 201 is, for example, several hundreds of nm.

In the Si antenna 251, the transmission signal Stx1 having a peak at a certain location corresponding to the pitch of the diffraction grating is outputted to the front surface of the Si layer at a predetermined angle. The heaters 252 each include a resistor element extending along the Si antenna 251. The heaters 252 each heat the Si antenna 251 by heat generation of the resistor element caused by application of a current to the resistor element in accordance with control by the controller 310. In the Si antenna 251, the refractive index is changed by heating by the heaters 252, and the transmission signal Stx1 is outputted at an angle corresponding to change in the refractive index.

The antenna 250 turns on and off the four optical switches 253, the two optical switches 254, and the one optical switch 255 in accordance with control by the controller 310. Thus, the antenna 250 outputs the transmission signal Stx1 in a predetermined direction from each of the antenna bodies, and receives the return signal Srx inputted from outside.

The coupler 260 is an element that generates a beat signal Sbt by interference between the transmission signal Stx2 and the return signal Srx. The frequency of the beat signal Sbt is changed in accordance with a frequency difference between the transmission signal Stx2 and the return signal Srx. The frequency difference is changed in accordance with a distance from the Si antenna 251 to the target TG. Accordingly, it is possible to estimate the distance from the Si antenna 251 to the target TG on the basis of the frequency of the beat signal Sbt.

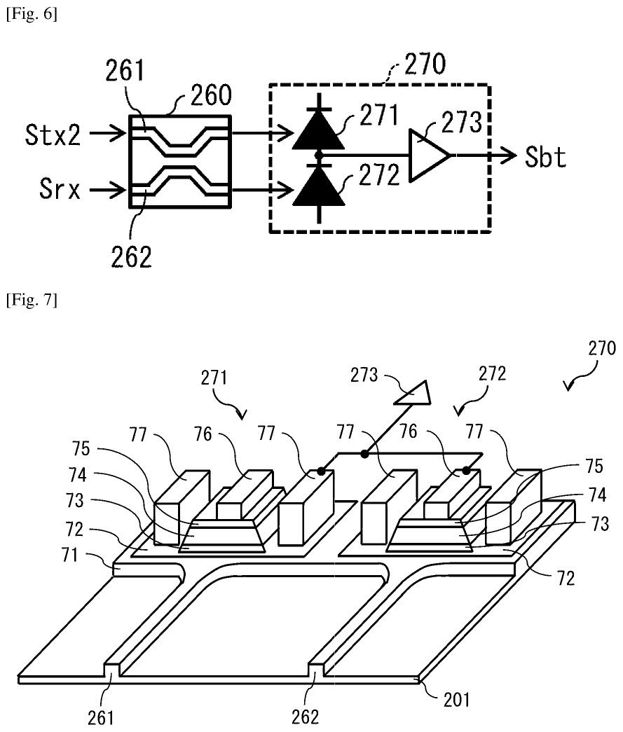

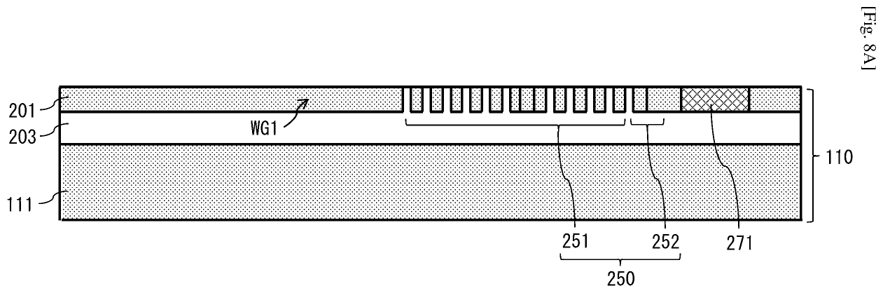

The coupler 260 includes, for example, an optical waveguide 261 for propagating the transmission signal Stx2, and an optical waveguide 262 for propagating the return signal Srx, as illustrated in FIG. 6. Each of the optical waveguides 261 and 262 is, for example, a rib waveguide. A portion of the optical waveguide 261 and a portion of the optical waveguide 262 are disposed in proximity to each other. This causes the transmission signal Stx2 that propagates through the optical waveguide 261 and the return signal Srx that propagates through the optical waveguide 262 to interfere with each other, thereby generating the beat signal Sbt.

The detector 270 is an element that extracts the beat signal Sbt from signals having propagated through the optical waveguides 261 and 262. The detector 270 includes, for example, Ge-PDs 271 and 272 that are coupled in series to each other, and a transimpedance amplifier 273 that is coupled to a coupling node between the Ge-PD 271 and the Ge-PD 272, as illustrated in FIG. 6.

The Ge-PD 271 is, for example, a PIN photodiode coupled to the optical waveguide 261 as illustrated in FIG. 7. The Ge-PD 272 is, for example, a PIN photodiode coupled to the optical waveguide 262 as illustrated in FIG. 7. The Ge-PDs 271 and 272 each include, for example, a Si terrace section 71 coupled to the optical waveguides 261 and 262, and a p-type Si layer 72. The p-type Si layer 72 is formed by ion-injecting B into the Si terrace section 71. The Si terrace section 71 and the optical waveguides 261 and 262 are provided in the common Si layer 201.

The Ge-PDs 271 and 272 each further include, for example, an island-shaped i-type Ge layer 73, a two-dimensionally grown i-type Ge layer 74, and an n-type Ge layer 75. The island-shaped i-type Ge layer 73 and the two-dimensionally grown i-type Ge layer 74 are provided on the p-type Si layer 72. The n-type Ge layer 75 is formed by ion-injecting P into the two-dimensionally grown i-type Ge layer 74. A stacked body including the p-type Si layer 72, the island-shaped i-type Ge layer 73, the two-dimensionally grown i-type Ge layer 74, and the n-type Ge layer 75 is included in the PIN photodiode. In the PIN photodiode, the island-shaped i-type Ge layer 73 that is ef-fectively of p-type and does not include a depletion layer has a small thickness, and the two-dimensionally grown i-type Ge layer 74 having a large thickness serves as a depletion layer, which improves sensitivity.

The Ge-PDs 271 and 272 each further include, for example, an n-side electrode 76 in contact with the n-type Ge layer75, and a p-side electrode 77 in contact with the p-type Si layer 72. The p-side electrode 77 of the Ge-PD 271 and the n-side electrode 76 of the Ge-PD 272 are coupled to each other by a wiring line, and the wiring line that couples the p-side electrode 77 of the Ge-PD 271 and the n-side electrode 76 of the Ge-PD 272 to each other is coupled to an input end of the transimpedance amplifier 273.

The transimpedance amplifier 273 performs impedance conversion and amplification of a current signal photoelectrically converted by the Ge-PDs 271 and 272, and outputs the beat signal Sbt as a voltage signal.

### (Lower Die 300)

The lower die 300 includes, for example, a controller 310, a DAC 320, an ADC 330, and a fast Fourier transform (FFT) 340, as illustrated in FIG. 1.

The controller 310 generates, for example, a control signal for controlling the laser 210, the modulator 220, the antenna 250, and the detector 270, and outputs the control signal to the DAC 320. The controller 310 further generates, for example, a control signal for controlling the ADC 330, and outputs the control signal to the ADC 330. The DAC 320 performs DA conversion of the control signal received from the controller 310, and outputs an thus-obtained analog control signal to the laser 210, the modulator 220, the antenna 250, and the detector 270. The ADC 330 performs AD conversion of the beat signal Sbt received from the detector 270, and outputs the beat signal Sbt to the FFT 340. The FFT 340 performs FFT of the beat signal Sbt being digital received from the ADC 330 to obtain power spectrum density, and derives the frequency of the beat signal Sbt on the basis of the obtained power spectrum density. The FFT 340 outputs information (frequency information) about the derived frequency to the controller 310. The controller 310 outputs the frequency information received from the FFT 340 to outside in accordance with control from the outside.

The lower die 300 includes, for example, a Si substrate 301 as illustrated in FIG. 2. The Si substrate 301 includes, for example, signal processing circuits such as the controller 310, the DAC 320, the ADC 330, and the FFT 340. An interlayer insulating film 302 is provided on the interlayer Si substrate 301. The interlayer insulating film 302 has a configuration in which a plurality of patterned wiring layers and a via that couples the wiring layers to each other are provided in a plurality of SiO₂ layers stacked. A wiring line and a via in the signal processing circuits, a wiring line and a via for electrically coupling the signal processing circuits and the upper die 200 to each other, and the like are provided in the interlayer insulating film 302. A coupling pad 303 including Cu is exposed on a front surface of the interlayer insulating film 302, and is joined to the coupling pad 204 of the upper die 200. In view of the description herein, it may be said that a first substrate 200 comprises one or more optical circuits that output a transmission signal Stx1 to an object (e.g., target TG) and that receive a reflected signal Srx from the object. The one or more optical circuits may include but are not limited to the laser 210 and modulator 220 (which may be integrated with one another and/or mounted on the first substrate 200), the waveguides WG1, WG2, and WG3, the splitter 230, the circulator 240, the antenna 250, the coupler 260, and/or the detector 270. Meanwhile, a second substrate 300 may comprise one or more electronic circuits that control generation of the transmission signal Stx1 and that process the reflected signal Srx. The one or more electronic circuits may include the controller 310, the DAC 320, the ADS330, and/or the FFT block 340.

### Manufacturing Method

Next, description is given of a method of manufacturing the distance measuring device 100.

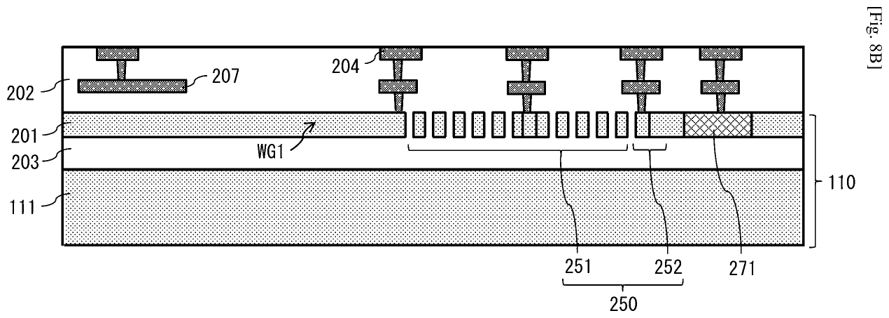

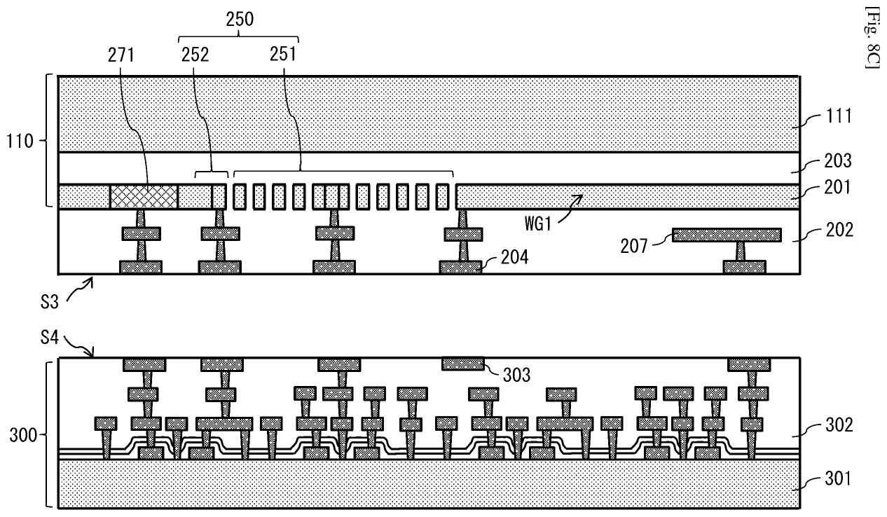

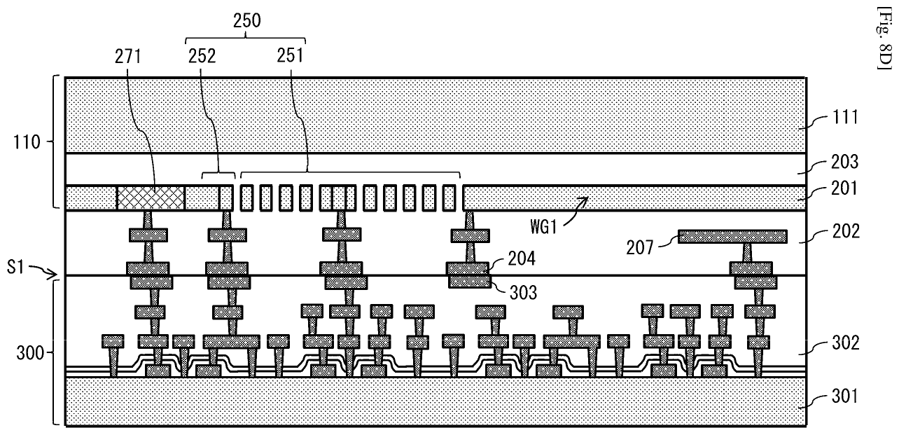

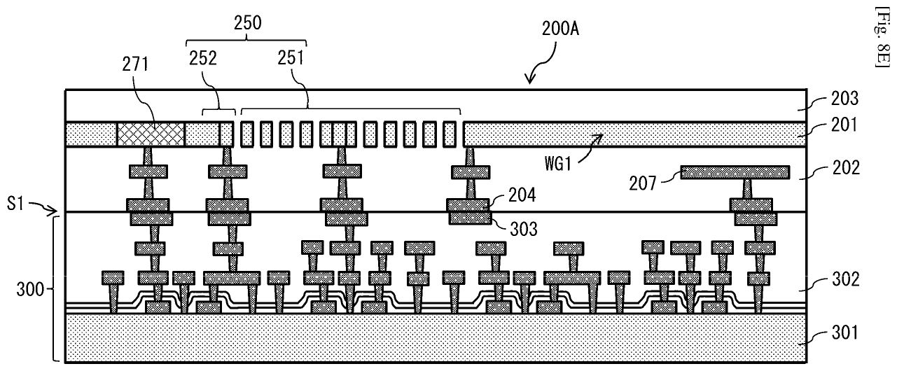

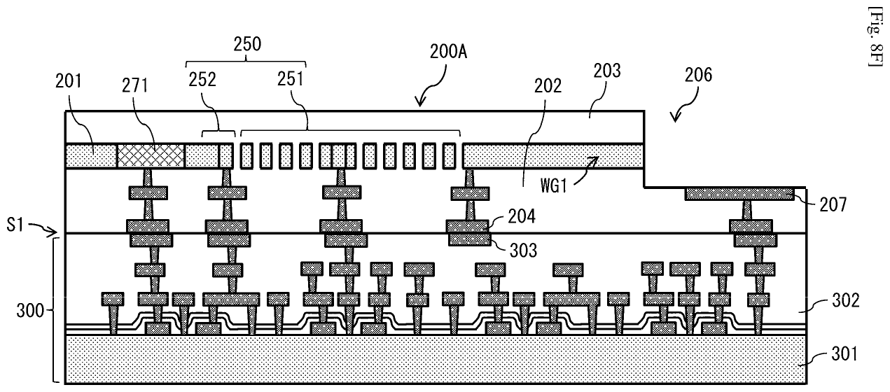

FIGS. 8A to 8G each are a cross-sectional view for describing a process of manufacturing the distance measuring device 100. First, the SOI substrate 110 is prepared (FIG. 8A). The SOI substrate 110 includes a substrate in which the BOX layer 203 and the Si layer 201 are provided on the Si substrate 111 in this order. Next, the optical waveguides WG1, WG2, and WG3, the splitter 230, the circulator 240, the Si antenna 251, the coupler 260, and portions (the Si terrace sections 71 and the p-type Si layers 72) of the Ge-PDs 271 and 272 are formed in the Si layer 201 of the SOI substrate 110 (FIG. 8A). Next, the interlayer insulating film 202 is formed on the SOI substrate 110 (FIG. 8B). On this occasion, the coupling pads 204 and 207 are formed in the interlayer insulating film 202.

Next, the SOI substrate 110 and the lower die 300 are bonded together with a front surface S3 of the interlayer insulating film 202 and a front surface S4 of the interlayer insulating film 302 opposed to each other (FIGS. 8C and 8D). Thus, the SOI substrate 110 and the lower die 300 are electrically coupled to each other. Next, the Si substrate 111 in the SOI substrate 110 is removed (FIG. 8E). Thus, the PIC substrate 200A is formed on the lower die 300. Next, the cutout section 206 is formed in the PIC substrate 200A (FIG. 8F). Thus, the coupling pad 207 is exposed on the bottom surface of the cutout section 206. Next, the laser 210 is mounted on the coupling pad 207 exposed on the bottom surface of the cutout section 206 with the bump 212 interposed therebetween (FIG. 8G). Finally, the lens 205 is disposed. Thus, the distance measuring device 100 is manufactured.

### Effects

Next, description is given of effects of the distance measuring device 100.

In the present embodiment, in the PIC substrate 200A, the optical waveguide WG1, the splitter 230, the optical waveguides WG2 and WG3, the coupler 260, and the Ge-PDs 271 and 272 are provided in the common Si layer 201. In addition, the ADC 330 and the detector 270 are provided in the lower die 300 (signal processing substrate). Furthermore, the PIC substrate 200A and the lower die 300 are stacked on each other, and are electrically coupled to each other through the joining surface S1 between the PIC substrate 200A and the lower die 300. This allows for downsizing, as compared with a module in which a plurality of RF components is coupled through an optical fiber. An electrical signal path subsequent to the Ge-PDs 271 and 272 is shortened by the downsizing, which makes it possible to reduce mixing of external noise into an electrical signal.

In the present embodiment, the modulator 220 and the Si antenna 251 are provided in the Si layer 201. The modulator 220 generates the transmission signal Stx (chirp signal). The Si antenna 251 outputs the transmission signal Stx1 divided from the transmission signal Stx to outside, and receives the return signal Srx from the outside. This allows for downsizing, as compared with a module in which a plurality of RF components is coupled through an optical fiber.

In the present embodiment, the chip-shaped laser 210 is mounted on the PIC substrate 200A, and the controller 310 that controls the laser 210, the modulator 220, and the antenna 250 is provided in the lower die 300. This allows for downsizing, as compared with a module in which a plurality of RF components is coupled through an optical fiber. A propagation path of the laser light L is shortened by the downsizing, which makes it possible to reduce loss of the laser light L.

In the present embodiment, the PIC substrate 200A and the lower die 300 are electrically coupled to each other by joining the coupling pads 204 and 303, which are provided on the joining surface S1 between the PIC substrate 200A and the lower die 300, to each other. This allows for downsizing, as compared with a module in which a plurality of RF components is coupled through an optical fiber. In addition, it is possible to expect an effect of enhancing quantum efficiency by reflection by the coupling pads 204 and 303.

In the present embodiment, the laser 210 includes an edge emitting laser, and is mounted on the PIC substrate 200A to set the light spot of the laser 210 at the same height as the Si layer 201 (optical waveguide WG1). The laser 210 inputs the light signal to the modulator 220 through the end surface of the optical waveguide WG1. This allows for downsizing, as compared with a module in which a plurality of RF components is coupled through an optical fiber.

In the present embodiment, the laser 210 and the PIC substrate 200A are electrically coupled to each other through the bump 212 provided between the laser 210 and the PIC substrate 200A. This makes it possible to accurately perform alignment of the laser 210.

### 2. Second Embodiment

### Configuration

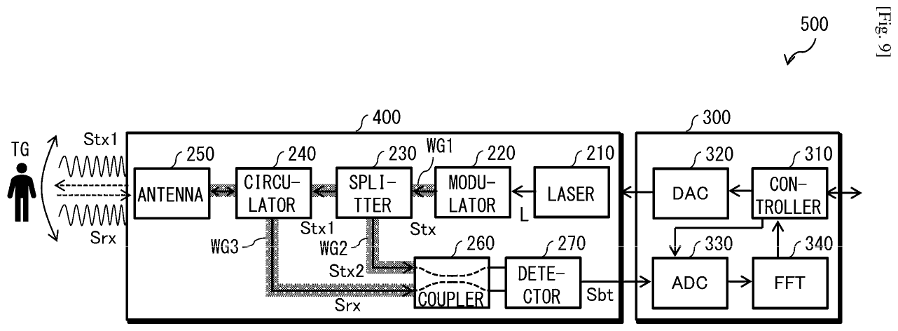

FIG. 9 illustrates a schematic configuration example of a distance measuring device 500 according to a second embodiment of the present disclosure. FIG. 10 illustrates a cross-sectional configuration example of the distance measuring device 500. The distance measuring device 500 differs from the distance measuring device 100 in that as a method of joining the PIC substrate 200A and the lower die 300 (signal processing substrate) to each other, a through-hole via 403 that penetrates through the joining surface S1 is used in place of joining between the coupling pads 204 and 303.

The distance measuring device 500 includes an FMCW LiDAR. The distance measuring device 500 includes, for example, an upper die 400 and the lower die 300, as illustrated in FIG. 9. For example, as illustrated in FIG. 10, the upper die 400 and the lower die 300 are stacked on each other, and are electrically coupled to each other through the through-hole via 403. That is, for example, as illustrated in FIG. 10, the upper die 400 and the lower die 300 are electrically coupled to each other through the joining surface S1 between the upper die 400 and the lower die 300.

### (Upper Die 400)

The upper die 400 includes, for example, the laser 210, the modulator 220, the splitter 230, the circulator 240, the antenna 250, the coupler 260, and the detector 270, as illustrated in FIG. 9. In the upper die 400, the modulator 220, the splitter 230, the circulator 240, the antenna 250, the coupler 260, and the detector 270 are provided in a PIC substrate 400A.

The laser 210 is mounted on the PIC substrate 400A to cause the laser light L to enter an end surface (optical waveguide WG1) of the PIC substrate 400A. The PIC substrate 400A has a cutout section 406, and the laser 210 is mounted on a coupling pad 408 provided on a bottom surface of the cutout section 406. The electrode of the laser 210 and the coupling pad 408 each include, for example, copper (Cu), and are joined to each other with the bump 212 including Cu interposed therebetween.

The PIC substrate 400A includes, for example, the Si layer 201, an insulating layer 401, and an interlayer insulating film 402, as illustrated in FIG. 10. The Si layer 201 is sandwiched between the insulating layer 401 and the interlayer insulating film 402. The Si layer 201 is obtained by removing the Si substrate 111 and the BOX layer 203 from the SOI substrate 110. The insulating layer 401 is a layer provided on the SOI substrate 110, and includes a SiO₂ layer. The interlayer insulating film 402 is a layer provided on the Si layer 201, and has a configuration in which a plurality of patterned wiring layers and a via that couples the wiring layers to each other are provided in a plurality of SiO₂ layers stacked.

A front surface of the insulating layer 401 serves as a bottom surface of the upper die 400. The front surface of the insulating layer 401 is in contact with the upper surface of the lower die 300 (interlayer insulating film 302). An front surface of the interlayer insulating film 402 serves as an upper surface of the upper die 400. A region, opposed to the Si antenna 251, of the front surface of the interlayer insulating film 402 serves as the entrance/exit surface S2.

The PIC substrate 400A has through-hole vias 403 and 407. The through-hole vias 403 and 407 each include a metal member extending in a thickness direction of the PIC substrate 400A.

The through-hole via 403 penetrates through a portion of the interlayer insulating film 402, the Si layer 201, and the insulating layer 401, and further penetrates through the joining surface S1 and a portion of the interlayer insulating film 302. A top of the through-hole via 403 is coupled to a wiring layer (e.g., a wiring layer 404 or the like) provided on the interlayer insulating film 402, and a bottom of the through-hole via 403 is coupled to a wiring layer provided in the interlayer insulating film 302. The through-hole via 403 is electrically coupled to an output end of the detector 270 and an input end of the ADC 330.

The through-hole via 407 penetrates through the insulating layer 401, and further penetrates through the joining surface S1 and a portion of the interlayer insulating film 302. A top of the through-hole via 407 is coupled to the coupling pad 408, and a bottom of the through-hole via 407 is coupled to a wiring layer provided in the interlayer insulating film 302. The through-hole via 407 is electrically coupled to the laser 210 and an output end of the DAC 320.

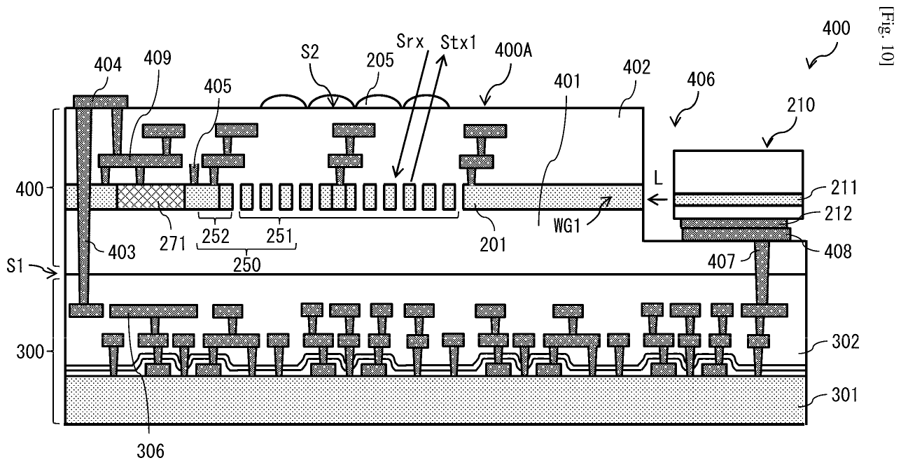

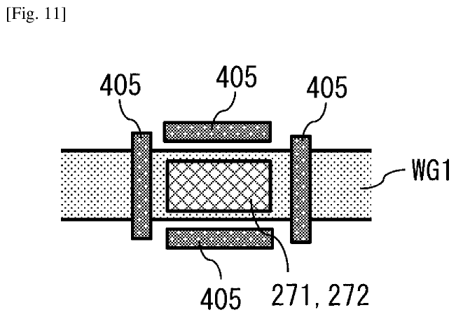

The PIC substrate 400A includes one or a plurality of light-shielding sections 405 surrounding Ge-PDs 271 and 272 in plan view, as illustrated in FIG. 11. The one or plurality of light-shielding sections 405 includes a via in the interlayer insulating film 402. The one or plurality of light-shielding sections 405 prevents (or alternatively, reduces) light leaked from the Si antenna 251 and hot carrier light emission from the lower die 300 from entering the Ge-PDs 271 and 272.

The PIC substrate 400A may include, for example, a light-shielding section 409 between the Ge-PDs 271 and 272 and the front surface of the interlayer insulating film 402, as illustrated in FIG. 10. The light-shielding section 409 covers the Ge-PDs 271 and 272 in plan view. The light-shielding section 409 includes, for example, a wiring layer in the interlayer insulating film 402. The light-shielding section 409 prevents (or alternatively, reduces) light from outside from entering the Ge-PDs 271 and 272.

The lower die 300 may include, for example, a light-shielding layer 306 provided at a position opposed to the Ge-PDs 271 and 272 between the Ge-PDs 271 and 272 and the Si substrate 301, as illustrated in FIG. 10. The light-shielding layer 306 includes, for example, a wiring layer in the interlayer insulating film 302. The light-shielding layer 306 prevents (or alternatively, reduces) hot carrier light emission from the lower die 300 from entering the Ge-PDs 271 and 272.

### Manufacturing Method

Next, description is given of a method of manufacturing the distance measuring device 500.

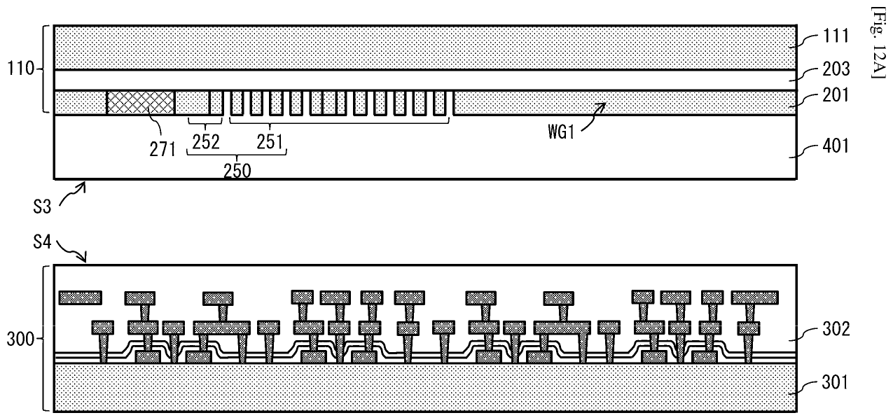

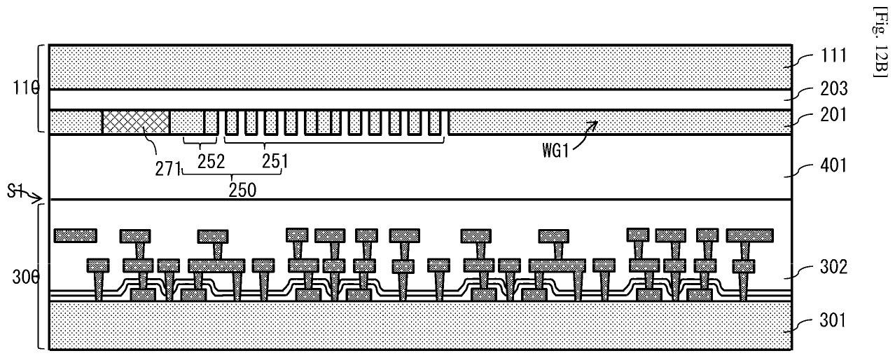

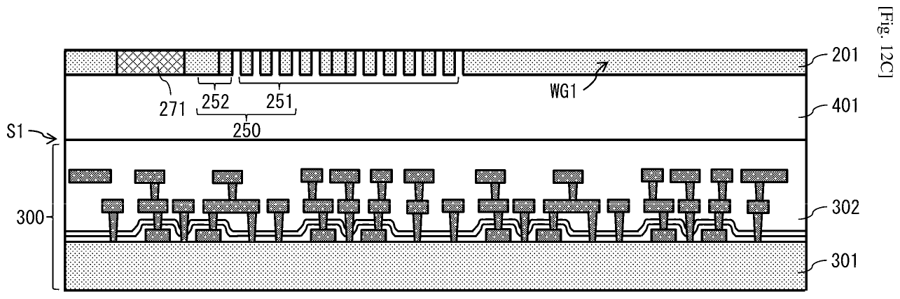

FIGS. 12A to 12G each are a cross-sectional view for describing a process of manufacturing the distance measuring device 500. First, the SOI substrate 110 in which the insulating layer 401 is provided, and the lower die 300 are prepared (FIG. 12A). Next, the SOI substrate 110 and the lower die 300 are bonded together with the front surface S3 of the insulating layer 401 and the front surface S4 of the interlayer insulating film 302 opposed to each other (FIGS. 12A and 12B). On this occasion, unlike the embodiment described above, electric coupling between the SOI substrate 110 and the lower die 300 is not formed.

Next, the Si substrate 111 and the BOX layer 203 are removed to expose the Si layer 201 (FIG. 12C). Next, the interlayer insulating film 402 is formed on the front surface of the Si layer 201 (FIG. 12D). Thus, the PIC substrate 400A is formed on the lower die 300. Next, after a through hole is formed that penetrates through the interlayer insulating film 402, the Si layer 201, the insulating layer 401, the joining surface S1, and a portion of the interlayer insulating film 302, the through hole is filled with a metal member to form the through-hole via 403 (FIG. 12E). Furthermore, the wiring layer 404 is formed, and electrically couples the through-hole via 403 and the output end of the detector 270 to each other.

Next, the cutout section 406 is formed (FIG. 12F). Subsequently, after a through hole that penetrates through the insulating layer 401 and a portion of the interlayer insulating film 302 is formed at the bottom surface of the cutout section 406, the through hole is filled with a metal member to form the through-hole via 407 (FIG. 12F). Next, the coupling pad 408 in contact with the through-hole via 407 is formed on the bottom surface of the cutout section 406. Furthermore, the laser 210 is mounted on the coupling pad 408 with the bump 212 interposed therebetween (FIG. 12G). Finally, the lens 205 is disposed. Thus, the distance measuring device 500 is manufactured.

### Effects

Next, description is given of effects of the distance measuring device 500.

In the present embodiment, in the PIC substrate 400A, the optical waveguide WG1, the splitter 230, the optical waveguides WG2 and WG3, the coupler 260, and the Ge-PDs 271 and 272 are provided in the common Si layer 201. In addition, the ADC 330 and the detector 270 are provided in the lower die 300 (signal processing substrate). Furthermore, the PIC substrate 400A and the lower die 300 are stacked on each other, and are electrically coupled to each other through the joining surface S1 between the PIC substrate 400A and the lower die 300. This allows for downsizing, as compared with a module in which a plurality of RF components is coupled through an optical fiber. An electrical signal path subsequent to the Ge-PDs 271 and 272 is shortened by the downsizing, which makes it possible to reduce mixing of external noise into an electrical signal.

In the present embodiment, the modulator 220 and the Si antenna 251 are provided in the Si layer 201. The modulator 220 generates the transmission signal Stx (chirp signal). The Si antenna 251 outputs the transmission signal Stx1 divided from the transmission signal Stx to outside, and receives the return signal Srx from the outside. This allows for downsizing, as compared with a module in which a plurality of RF components is coupled through an optical fiber.

In the present embodiment, the chip-shaped laser 210 is mounted on the PIC substrate 400A, and the controller 310 that controls the laser 210, the modulator 220, and the antenna 250 is provided in the lower die 300. This allows for downsizing, as compared with a module in which a plurality of RF components is coupled through an optical fiber. A propagation path of the laser light L is shortened by the downsizing, which makes it possible to reduce loss of the laser light L.

In the present embodiment, the PIC substrate 400A and the lower die 300 are electrically coupled to each other by the through-hole via 403 that penetrates through the joining surface S1 between the PIC substrate 400A and the lower die 300. This allows for downsizing, as compared with a module in which a plurality of RF components is coupled through an optical fiber.

In the present embodiment, the laser 210 includes an edge emitting laser, and is mounted on the PIC substrate 400A to set the light spot of the laser 210 at the same height as the Si layer 201 (optical waveguide WG1). The laser 210 inputs the light signal to the modulator 220 through the end surface of the optical waveguide WG1. This allows for downsizing, as compared with a module in which a plurality of RF components is coupled through an optical fiber.

In the present embodiment, the laser 210 and the PIC substrate 400A are electrically coupled to each other through the bump 212 provided between the laser 210 and the PIC substrate 400A. This makes it possible to accurately perform alignment of the laser 210.

### 3. Third Embodiment

### Configuration

FIG. 13 illustrates a schematic configuration example of a distance measuring device 600 according to a third embodiment of the present disclosure. FIG. 14 illustrates a cross-sectional example of the distance measuring device 600. The distance measuring device 600 includes an FMCW LiDAR. The distance measuring device 600 includes, for example, a lower die 700 and an upper chip 800 (signal processing substrate), as illustrated in FIG. 13.

For example, as illustrated in FIG. 14, the lower die 700 and the upper chip 800 are stacked on each other, and are electrically coupled to each other through the joining surface S1 between the lower die 700 and the upper chip 800. The upper chip 800 has a chip shape smaller in size than the PIC substrate 700A included in the lower die 700, and is mounted on a front surface of the PIC substrate 700A. For example, the upper chip 800 has a smaller footprint (e.g., surface area) in a plan view than the footprint of the lower die 700.

### (Lower Die 700)

The lower die 700 includes, for example, the laser 210, the modulator 220, the splitter 230, the circulator 240, the antenna 250, the coupler 260, and the detector 270, as illustrated in FIG. 13. In the lower die 700, the modulator 220, the splitter 230, the circulator 240, the antenna 250, the coupler 260, and the detector 270 are provided in the PIC substrate 700A.

The laser 210 is mounted on the PIC substrate 700A to cause the laser light L to enter an end surface (optical waveguide WG1) of the PIC substrate 700A. The laser 210 is mounted on the PIC substrate 700A to set the light spot of the laser 210 at the same height as the Si layer 201 (optical waveguide WG1). The PIC substrate 700A has a cutout section 701, and the laser 210 is mounted on a coupling pad 702 provided on a bottom surface of the cutout section 701. The electrode of the laser 210 and the coupling pad 702 each include, for example, copper (Cu), and are joined to each other with the bump 212 including Cu interposed therebetween.

The PIC substrate 700A includes, for example, a substrate in which the BOX layer 203, the Si layer 201, and the interlayer insulating film 202 are stacked in this order on the Si substrate 111, as illustrated in FIG. 14. The Si substrate 111, the BOX layer 203, and the Si layer 201 are included in the SOI substrate 110. The interlayer insulating film 202 is a layer provided on the SOI substrate 110, and has a configuration in which a plurality of patterned wiring layers and a via that couples the wiring layers to each other are provided in a plurality of SiO₂ layers stacked. The front surface of the interlayer insulating film 202 serves as an upper surface of the lower die 700, and is in contact with a bottom surface of the upper chip 800 (interlayer insulating film 302). The coupling pad 204 including Cu is exposed on the front surface of the interlayer insulating film 202. In contrast, the coupling pad 303 including Cu is exposed on an upper surface of the upper chip 800 (interlayer insulating film 302). The coupling pad 204 and the coupling pad 303 are joined to each other. This causes the PIC substrate 700A and the upper chip 800 to be joined to each other on the upper surface of the PIC substrate 700A and the bottom surface of the upper chip 800. In FIG. 14, a joining surface between the upper surface of the lower die 700 and the bottom surface of the upper chip 800 (interlayer insulating film 302) is expressed as S1. The bottom surface of the Si substrate 111 serves as the bottom surface of the lower die 700, and serves as the entrance/exit surface S2.

### (Upper Chip 800)

The upper chip 800 includes, for example, the controller 310, the DAC 320, the ADC 330, and the FFT 340, as illustrated in FIG. 13. The upper chip 800 includes, for example, a Si substrate 301, as illustrated in FIG. 14. The Si substrate 301 includes, for example, signal processing circuits such as the controller 310, the DAC 320, the ADC 330, and the FFT 340. The interlayer insulating film 302 is provided on the Si substrate 301. The interlayer insulating film 302 has a configuration in which a plurality of patterned wiring layers and a via that couples the wiring layers to each other are provided in a plurality of SiO₂ layers stacked. A wiring line and a via in the signal processing circuits, and a wiring line and a via for electrically coupling the signal processing circuits and the lower die 700 to each other, and the like are provided in the interlayer insulating film 302. The coupling pad 303 including Cu is exposed on the front surface of the interlayer insulating film 302, and is joined to the coupling pad 204 of the lower die 700. The laser 210 is electrically coupled to the upper chip 800 by a bonding wire, for example.

A marker 703 is provided in the lower die 700. In contrast, a marker 304 is provided in the upper chip 800. The markers 703 and 304 are used to perform alignment of the upper chip 800 upon mounting the upper chip 800 on the lower die 700. The marker 703 includes a portion of a wiring layer provided in the interlayer insulating film 202. The marker 304 includes a portion of a wiring layer provided in the interlayer insulating film 302. For example, as illustrated in FIG. 14, to secure visibility with infrared light, the markers 703 and 304 are disposed in a region not opposed to the Ge-PDs 271 and 272 in plan view. The marker 703 may configure a portion of the coupling pad 204. In addition, the marker 304 may configure a portion of the coupling pad 303.

### Effects

Next, description is given of effects of the distance measuring device 600.

In the present embodiment, in the PIC substrate 700A, the optical waveguide WG1, the splitter 230, the optical waveguides WG2 and WG3, the coupler 260, and the Ge-PDs 271 and 272 are provided in the common Si layer 201. In addition, the ADC 330 and the detector 270 are provided in the upper chip 800 (signal processing substrate). Furthermore, the PIC substrate 700A and the upper chip 800 are stacked on each other, and are electrically coupled to each other through the joining surface S1 between the PIC substrate 700A and the upper chip 800. This allows for downsizing, as compared with a module in which a plurality of RF components is coupled through an optical fiber. An electrical signal path subsequent to the Ge-PDs 271 and 272 is shortened by the downsizing, which makes it possible to reduce mixing of external noise into an electrical signal.

In the present embodiment, the modulator 220 and the Si antenna 251 are provided in the Si layer 201. The modulator 220 generates the transmission signal Stx (chirp signal). The Si antenna 251 outputs the transmission signal Stx1 divided from the transmission signal Stx to outside, and receives the return signal Srx from the outside. This allows for downsizing, as compared with a module in which a plurality of RF components is coupled through an optical fiber.

In the present embodiment, the chip-shaped laser 210 is mounted on the PIC substrate 700A, and the controller 310 that controls the laser 210, the modulator 220, and the antenna 250 are provided in the upper chip 800. This allows for downsizing, as compared with a module in which a plurality of RF components is coupled through an optical fiber. A propagation path of the laser light L is shortened by the downsizing, which makes it possible to reduce loss of the laser light L.

In the present embodiment, the PIC substrate 700A and the upper chip 800 are electrically coupled to each other by joining the coupling pads 204 and 303 provided on the joining surface S1 between the PIC substrate 800A and the upper chip 800 to each other. This allows for downsizing, as compared with a module in which a plurality of RF components is coupled through an optical fiber.

In the present embodiment, the laser 210 includes an edge emitting laser, and is mounted on the PIC substrate 700A to set the light spot of the laser 210 at the same height as the Si layer 201 (optical waveguide WG1). The laser 210 inputs the light signal to the modulator 220 through the end surface of the optical waveguide WG1. This allows for downsizing, as compared with a module in which a plurality of RF components is coupled through an optical fiber.

In the present embodiment, the marker 703 is provided in the lower die 700, and the marker 304 is provided in the upper chip 800. This makes it possible to mount the upper chip 800 on the lower die 700 while applying infrared rays to the markers 703 and 304 to check the positions of the marker 703 and 304, for example. This makes it possible to accurately dispose the upper chip 800 on the lower die 700. As may be appreciated, the distance measuring device 600 of FIGS. 13 and 14 may be formed by a Chip-on-Wafer (CoW) wafer process where a plurality of upper chips 800 are formed in a single silicon wafer and diced to form individual upper chips 800. Thereafter, each individual upper chip 800 is tested (e.g., to ensure proper electrical function of transistors). Only upper chips 800 that pass testing are placed on a support substrate (e.g., 301) and then bonded to another wafer (e.g., 111) that includes a plurality of PIC substrates 700A to form a plurality of distance measuring devices 600. Thereafter, dicing may be performed on the bonded structures to form individual distance measuring devices 600 with each having an upper chip 800 bonded to a lower die 700. As may be appreciated, the CoW process may increase theoretical yield (by reducing dead space caused by defective chips) and reduce the risk of having defective distance measuring devices compared to a wafer-on-wafer (WoW) process in which a wafer of upper dies 200 is bonded to a wafer of lower dies 300 prior to dicing and/or testing the lower dies 300 (see the embodiment of FIG. 2 for a distance measuring device that may be formed according to a WoW process).

### 4. Modification Examples of Third Embodiment

FIGS. 15 and 16 each illustrate a modification example of a schematic configuration of the distance measuring device 600. For example, as illustrated in FIG. 15, a wiring layer 704 may be provided at a position opposed to the marker 703 in the interlayer insulating film 202. In addition, for example, as illustrated in FIG. 16, a Ge-PD 705 may be provided at a position opposed to the marker 703 in the Si layer 201. In such a case, for example, when infrared light rays are applied to the markers 703 and 304 from side of the upper chip 800, the infrared light rays are reflected by the wiring layer 704 and the Ge-PD 705, which makes it possible to accurately dispose the upper chip 800 on the lower die 700.

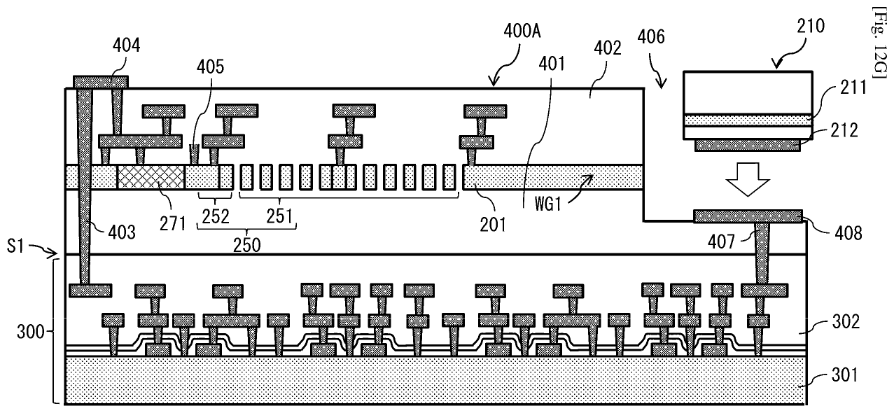

It is to be noted that, for example, as illustrated in FIG. 17, the PIC substrate 700A may have a groove section 709, and the wiring layer 704 may be provided on a bottom surface of the groove section 709. On this occasion, the upper chip 800 may be mounted in the groove section 709 to electrically couple the coupling pad 303 of the upper chip 800 and the wiring layer 704 in the groove section 709 to each other. In such a case, downsizing is possible by an embedded portion of the upper chip 800 in the groove section 709.

### 5. Fourth Embodiment

### Configuration

FIG. 18 illustrates a schematic configuration example of a distance measuring device 1100 according to a fourth embodiment of the present disclosure. FIG. 19 illustrates a cross-sectional configuration example of the distance measuring device 1100. The distance measuring device 1100 uses vias 1210 and 1230 as electrical coupling between an element such as the laser 210, the modulator 220, the antenna 250, or the detector 270 and a signal processing circuit such as the controller 310, the DAC 320, the ADC 330, or the FFT 340. Lower ends of the vias 1210 and 1230 each are coupled to a gate or a diffusion region (source-drain) of a transistor used in the signal processing circuit, and upper ends of the vias 1210 and 1230 each are coupled to a wiring layer provided in an interlayer insulating film.

The distance measuring device 1100 includes an FMCW LiDAR. The distance measuring device 1100 includes an upper layer 1200 and a lower layer 1300, as illustrated in FIG. 18. For example, as illustrated in FIG. 19, the upper layer 1200 is provided on the lower layer 1300, and a wiring layer provided in the upper layer 1200 and a gate or a diffusion region (source-drain) of a transistor provided in the lower layer 1300 are electrically coupled to each other through the vias 1210 and 1230. That is, for example, as illustrated in FIG. 19, the upper layer 1200 and the lower layer 1300 are electrically coupled to each other through a surface where the upper layer 1200 and the lower layer 1300 are in contact with each other.

### (Upper Layer 1200)

The upper layer 1200 includes, for example, the laser 210, the modulator 220, the splitter 230, the circulator 240, the antenna 250, the coupler 260, and the detector 270, as illustrated in FIG. 18. In the upper layer 1200, the modulator 220, the splitter 230, the circulator 240, the antenna 250, the coupler 260, and the detector 270 are provided in a PIC layer 1200A.

The laser 210 is mounted on the PIC layer 1200A to cause the laser light L to enter an end surface (optical waveguide WG1) of the PIC layer 1200A. The PIC layer 1200A has the cutout section 406, and the laser 210 is mounted on the coupling pad 408 provided on the bottom surface of the cutout section 406. The electrode of the laser 210 and the coupling pad 408 each include, for example, copper (Cu), and are joined to each other with the bump 212 including Cu interposed therebetween.

The PIC layer 1200A includes, for example, the Si layer 201, the insulating layer 401, and the interlayer insulating film 402, as illustrated in FIG. 19. The Si layer 201 is sandwiched between the insulating layer 401 and the interlayer insulating film 402. The insulating layer 401 is a layer provided on the lower layer 1300, and includes a SiO₂ layer. The Si layer 201 is a layer provided on the insulating layer 401. The interlayer insulating film 402 is a layer provided on the Si layer 201, and has a configuration in which a plurality of patterned wiring layers and a via that couples the wiring layers to each other are provided in a plurality of SiO₂ layers stacked. The front surface of the interlayer insulating film 402 serves as an upper surface of the PIC layer 1200A. A region, opposed to the Si antenna 251, of the front surface of the interlayer insulating film 402 serves as the entrance/exit surface S2.

The PIC layer 1200A has the vias 1210 and 1230. The vias 1210 and 1230 each include a metal member extending in a thickness direction of the PIC layer 1200A.

The via 1210 penetrates through a portion of the interlayer insulating film 402, the Si layer 201, and the insulating layer 401, and further penetrates through an insulating layer 305 (to be described later) of the lower layer 1300. A top of the via 1210 is coupled to a wiring layer (e.g., a wiring layer 1220 or the like) provided in the interlayer insulating film 402, and a bottom of the via 1210 is coupled to a gate or a diffusion region (source-drain) of a transistor provided in the Si substrate 301 of the lower layer 1300. The via 1210 is coupled to the output end of the detector 270 and the input end of the ADC 330.

The via 1230 penetrates through the insulating layer 401, and further penetrates through the insulating layer 305 (to be described later) of the lower layer 1300. A top of the via 1230 is coupled to the coupling pad 408, and a bottom of the via 1230 is coupled to a gate or a diffusion region (source-drain) of a transistor provided in the Si substrate 301 of the lower layer 1300. The via 1230 electrically couples the laser 210 and the output end of the DAC 320 to each other.

The lower layer 1300 includes, for example, the controller 310, the DAC 320, the ADC 330, and the FFT 340, as illustrated in FIG. 18.

The lower layer 1300 includes, for example, the Si substrate 301, as illustrated in FIG. 19. The Si substrate 301 includes, for example, signal processing circuits such as the controller 310, the DAC 320, the ADC 330, and the FFT 340. The insulating layer 305 is provided on the Si substrate 301. The insulating layer 305 includes a SiO₂ layer.

### Manufacturing Method

Next, description is given of a method of manufacturing the distance measuring device 1100.

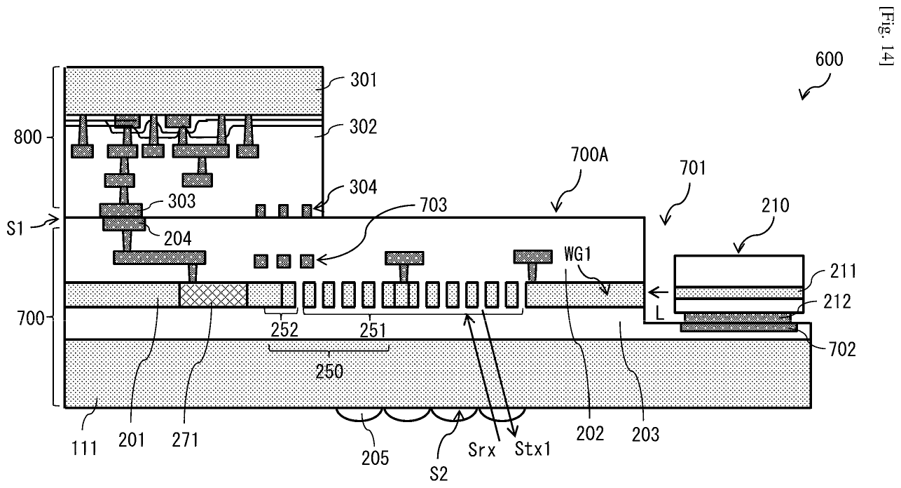

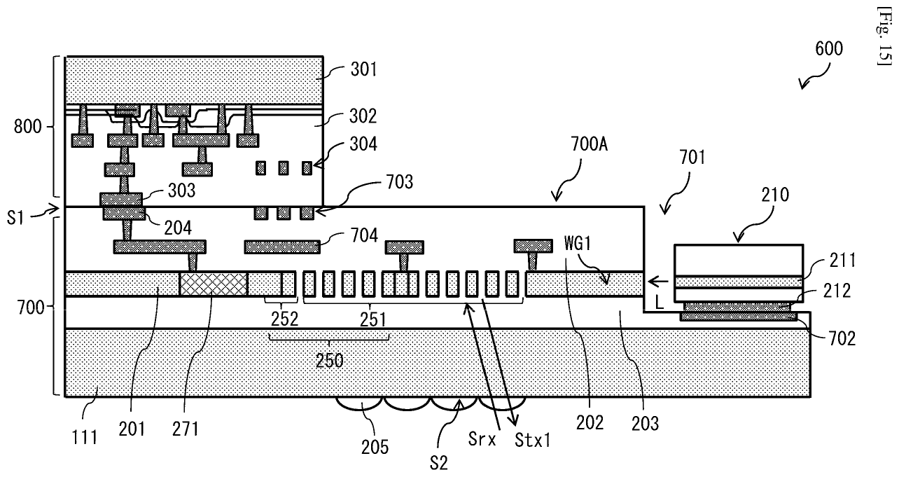

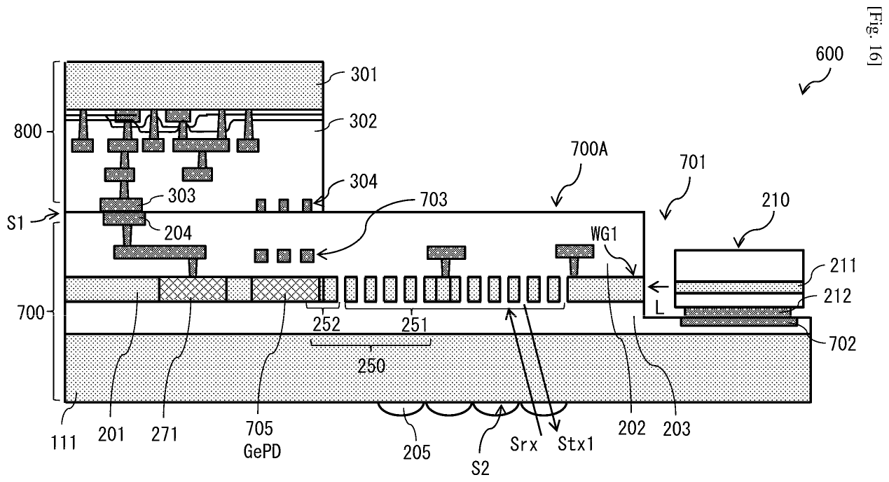

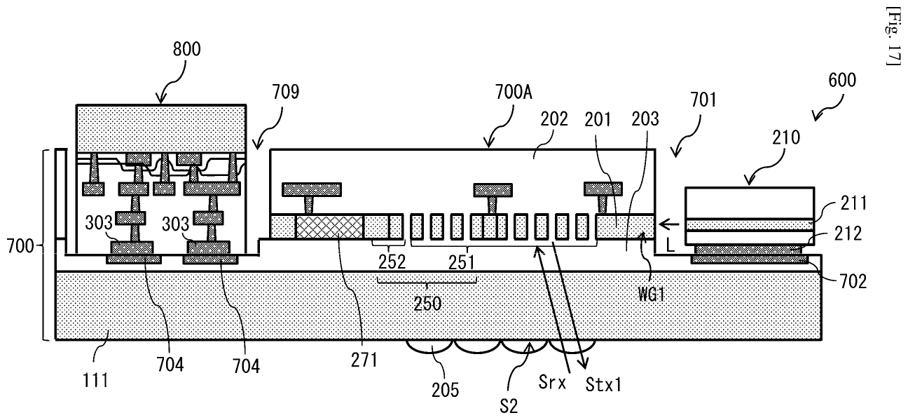

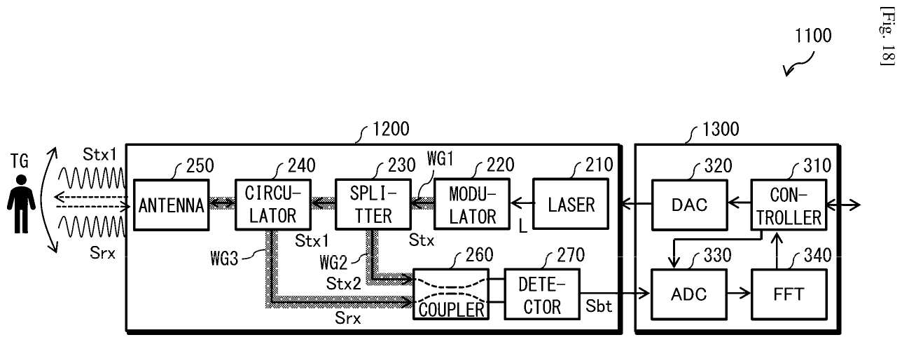

FIGS. 20A to 20F each are a cross-sectional view for describing a process of manufacturing the distance measuring device 1100. First, the lower layer 1300 in which the insulating layer 305 is provided on the Si substrate 301 is prepared (FIG. 20A). Next, the Si layer 201 is formed on the lower layer 1300, and the optical waveguides WG1, WG2, and WG3, the splitter 230, the circulator 240, the Si antenna 251, the coupler 260, portions (the Si terrace sections 71 and the p-type Si layers 72) of the Ge-PDs 271 and 272 are formed in the Si layer 201 (FIG. 20B).

Next, after an insulating layer 402a is formed on the Si layer 201, a through hole that penetrates through the insulating layer 402a, the Si layer 201, the insulating layer 401, and the insulating layer 305 is formed, and the through hole is filled with a metal member to form the via 1210 (FIG. 20C). Next, an interlayer insulating film is formed on the insulating layer 402a to form the interlayer insulating film 402 on the Si layer 201 (FIG. 20D). On this occasion, the wiring layer 1220 is formed to be in contact with the top of the via 1210. Thus, the PIC layer 1200A is formed on the lower layer 1300.

Next, the cutout section 406 is formed (FIG. 20E). Next, after a through hole that penetrates through the insulating layers 401 and 305 is formed at the bottom surface of the cutout section 406, the through hole is filled with a metal member to form the via 1230 (FIG. 20E). Next, the coupling pad 408 in contact with the via 1230 is formed on the bottom surface of the cutout section 406. Furthermore, the laser 210 is mounted on the coupling pad 408 with the bump 212 interposed therebetween (FIG. 20F). Finally, the lens 205 is disposed. Thus, the distance measuring device 1100 is manufactured.

### Effects

Next, description is given of effects of the distance measuring device 1100.

In the present embodiment, in the PIC layer 1200A, the optical waveguide WG1, the splitter 230, the optical waveguides WG2 and WG3, the coupler 260, and the Ge-PDs 271 and 272 are provided in the common Si layer 201. In addition, the ADC 330 and the detector 270 are provided in the lower layer 1300 (signal processing substrate). Furthermore, the PIC layer 1200A is provided on the lower layer 1300, and the lower layer 1300 and the PIC layer 1200A are electrically coupled to each other through a surface where the lower layer 1300 and the PIC layer 1200A are in contact with each other. This allows for downsizing, as compared with a module in which a plurality of RF components is coupled through an optical fiber. An electrical signal path subsequent to the Ge-PDs 271 and 272 is shortened by the downsizing, which makes it possible to reduce mixing of external noise into an electrical signal.

In the present embodiment, the modulator 220 and the Si antenna 251 are provided in the Si layer 201. The modulator 220 generates the transmission signal Stx (chirp signal). The Si antenna 251 outputs the transmission signal Stx1 divided from the transmission signal Stx to outside, and receives the return signal Srx from the outside. This allows for downsizing, as compared with a module in which a plurality of RF components is coupled through an optical fiber.

In the present embodiment, the chip-shaped laser 210 is mounted on the PIC layer 1200A, and the controller 310 that controls the laser 210, the modulator 220, and the antenna 250 is provided in the lower layer 1300. This allows for downsizing, as compared with a module in which a plurality of RF components is coupled through an optical fiber. A propagation path of the laser light L is shortened by the downsizing, which makes it possible to reduce loss of the laser light L.

In the present embodiment, the PIC layer 1200A and the lower layer 1300 are electrically coupled to each other through the via 1210 that penetrates through a surface where the PIC layer 1200A and the lower layer 1300 are in contact with each other. This allows for downsizing, as compared with a module in which a plurality of RF components is coupled through an optical fiber.

In the present embodiment, the laser 210 includes an edge emitting laser, and is mounted on the PIC layer 1200A to set the light spot of the laser 210 at the same height as the Si layer 201 (optical waveguide WG1). The laser 210 inputs the light signal to the modulator 220 through the end surface of the optical waveguide WG1. This allows for downsizing, as compared with a module in which a plurality of RF components is coupled through an optical fiber.

In the present embodiment, the laser 210 and the PIC layer 1200A are electrically coupled to each other through the bump 212 provided between the laser 210 and the PIC layer 1200A. This makes it possible to accurately perform alignment of the laser 210.

### 6. Modification Example of Fourth Embodiment

FIG. 21 illustrates a modification example of a schematic configuration of the distance measuring device 1100. In the present modification example, the lower layer 1300 may include a shallow trench isolation (STI) section 1240 at a location opposed to the Si antenna 251. The STI section 1240 has, for example, a depth reaching the Si substrate 301 from the front surface of the insulating layer 305. In the lower layer 1300, a trench having a depth reaching the Si substrate 301 from the front surface of the insulating layer 305 is provided, and the trench is filled with an insulating material to form the STI section 1240. Examples of the insulating material used for the STI section 1240 include silicon oxide. In such a case, a portion of the transmission signal Stx1 outputted from the Si antenna 251 is reflected by the lower layer 1300, which makes it possible to suppress occurrence of a side lobe (beam divergence) in the transmission signal Stx1.

### 7. Modification Examples of Embodiments

Description is given of modification examples of the embodiments described above. In the following modification examples, common components to those in the embodiments described above are denoted by same reference signs.

### Modification Example A

In the embodiments described above and the modification examples thereof, for example, as illustrated in FIG. 22, a tapered optical waveguide section 208 may be provided in the PIC substrate 200A. The tapered optical waveguide section 208 has an end surface on a surface continuous with the end surface of the optical waveguide WG1. The optical waveguide section 208 includes, for example, SiN or SiON, and is formed by an etching process using a grayscale resist. In such a case, it is sufficient if the laser 210 is mounted on the PIC substrate 200A to set the light spot (active layer 211) of the laser 210 in the same layer as the Si layer 201 (optical waveguide WG1) and the optical waveguide section 208. As a result, it is possible to moderate alignment accuracy of the laser 210.

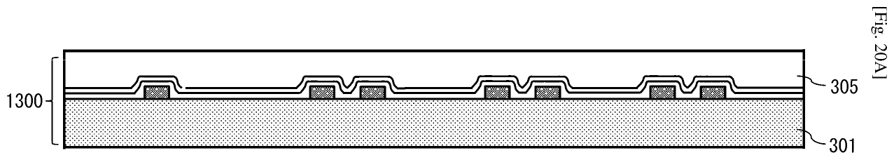

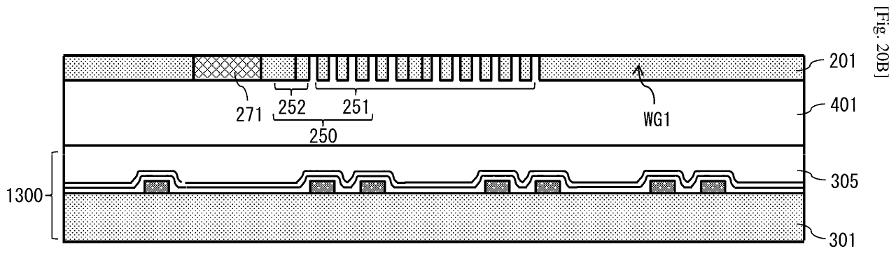

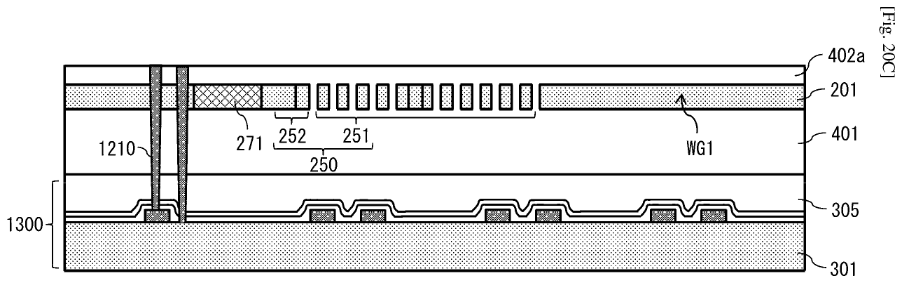

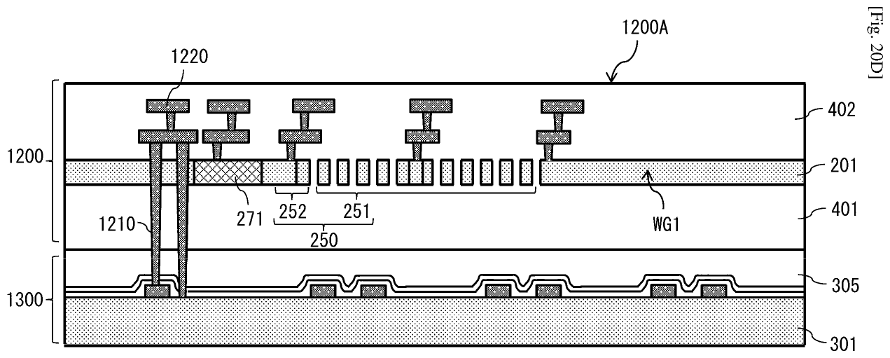

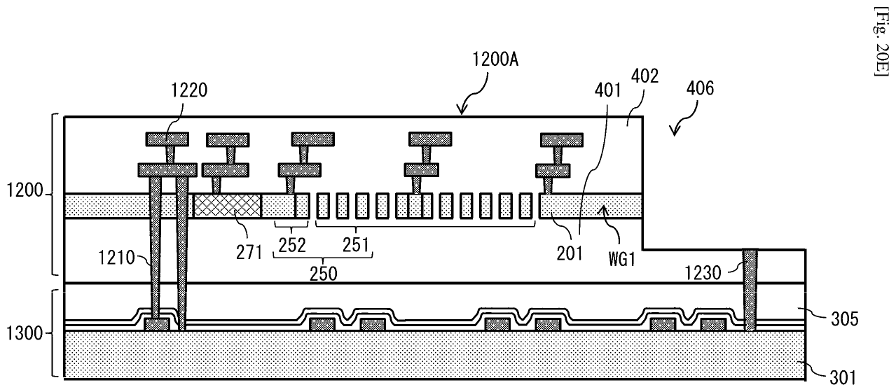

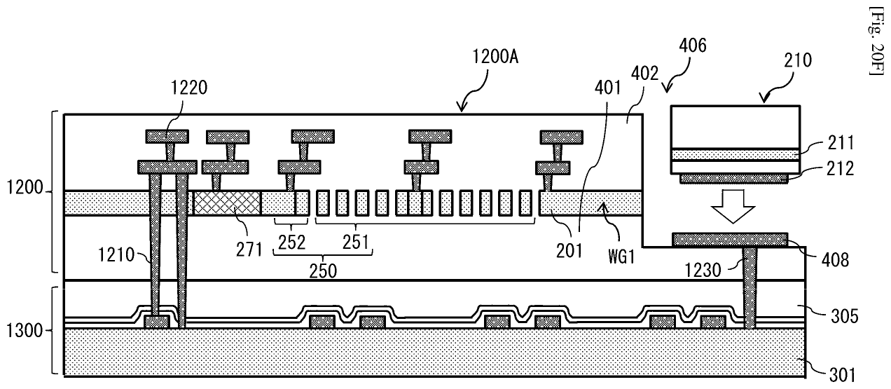

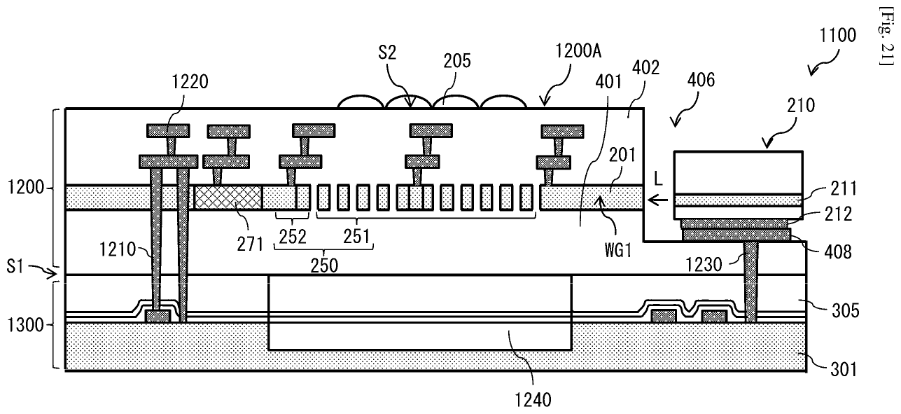

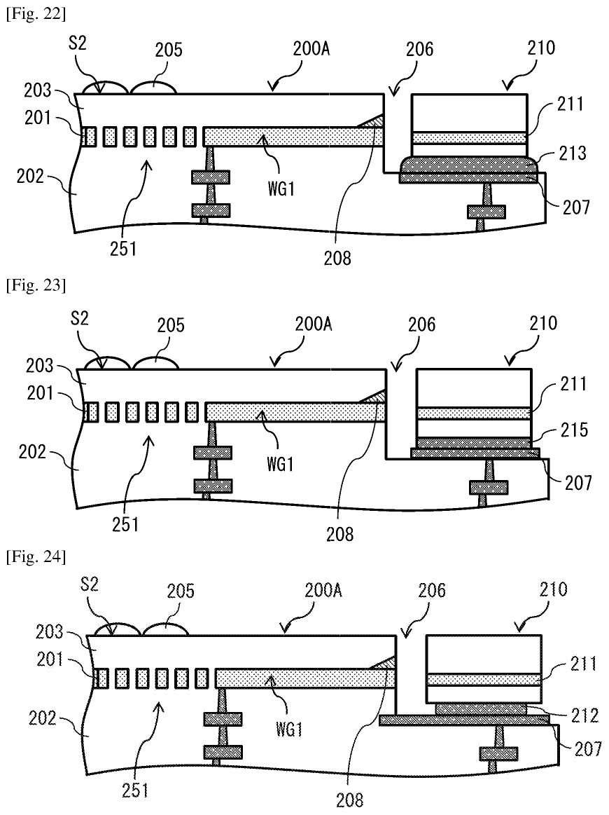

FIGS. 22, 23, and 24 each illustrate a modification example of a method of mounting the laser 210 on the PIC substrate 200A. In the present modification example, for example, as illustrated in FIG. 22, the laser 210 may be mounted on the PIC substrate 200A with a solder 213 interposed therebetween. For example, as illustrated in FIG. 23, the laser 210 may be mounted on the PIC substrate 200A by joining the electrode (Cu electrode 215) of the laser 210 and the coupling pad 207 including Cu to each other. For example, as illustrated in FIG. 24, the laser 210 may be mounted on the coupling pad 207 embedded in the PTC substrate 200A with the bump 212 interposed therebetween. Thus, in the present modification example, various methods are applicable as the method of mounting the laser 210 on the PIC substrate 200A.

### Modification Example B

In the embodiments described above and modification examples thereof, a laser 280 that emits the laser light L in a stacking direction may be used in place of the laser 210 that emits the laser light L from the end surface. The laser 280 includes a vertical cavity surface emitting laser (VCSEL). The laser 280 includes, for example, an active layer 281 and a pair of distributed Bragg reflector (DBR) layers, as illustrated in FIG. 25. The active layer 281 is sandwiched between the pair of the DBR layers in a thickness direction.

The PIC substrate 200A may include, for example, an optical coupler 209 at a location opposed to the laser 280, as illustrated in FIG. 25. The optical coupler 209 guides the laser light L emitted from the laser 280 to the optical waveguide WG1. On this occasion, the optical coupler 209 includes, for example, a diffraction grating provided in the Si layer 201.

The PIC substrate 700A may include, for example, the optical coupler 209 as illustrated in FIG. 26. On this occasion, the Si substrate 111 may have, for example, an opening 111a, into which the laser 280 is fitted, at a location opposed to the laser 280. On this occasion, the laser 280 is fitted into the opening 111a. A resin or the like may be provided in the opening 111a to fix the laser 280.

As described above, the vertical cavity surface emitting laser is used as a light source that outputs a light signal, and the light signal outputted from the surface emitting laser is guided to the optical waveguide WG1 with use of the optical coupler 209. This makes it possible to align the optical waveguide WG1 and the surface emitting laser by self-alignment, which makes it possible to reduce light loss due to misalignment and enhance coupling efficiency.

In the present modification example, an optical element (e.g., a prism 290) may be provided that refracts the laser light L emitted from the laser 280 to cause the laser light L to obliquely enter the optical coupler 209. The prism 290 is provided between the laser 280 and the optical coupler 209. For example, the prism 290 may be provided in the interlayer insulating film 202 as illustrated in FIG. 27. This makes it possible to efficiently propagate the laser light L to the Si antenna 251 in the optical coupler 209. As a result, it is possible to further enhance optical coupling between the optical waveguide WG1 and the surface emitting laser.

In the present modification example, the laser 280 may emit the laser light L in a direction obliquely intersecting with the stacking direction. For example, a composite photonic crystal layer is provided adjacent to the active layer 281 in the laser 280. In the composite photonic crystal layer, a period difference between two types of photonic crystals is continuously changed. Furthermore, in the laser 280, divided electrodes are disposed in multiple stages. Accordingly, while some adjacent electrodes of a plurality of electrodes disposed in multiple stages are simultaneously driven, driving positions of the electrodes are shifted one by one in order, which makes it possible to cause photonic crystal (resonator) sections having various lattice constant differences to oscillate by selectively exciting the photonic crystal sections. As a result, it is possible to change an emission angle of the laser light L in accordance with an ex-citation position.

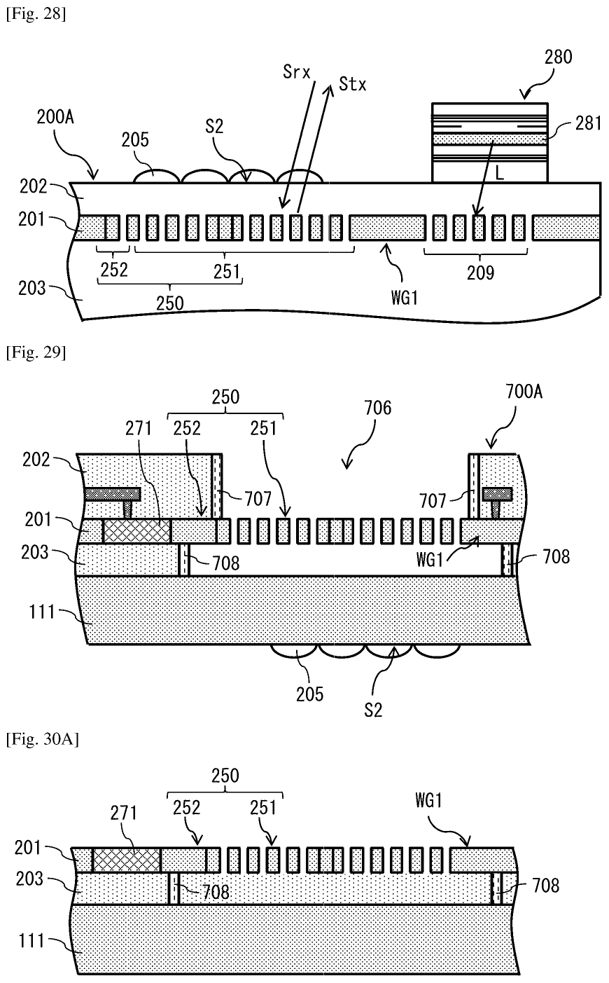

In the present modification example, for example, as illustrated in FIG. 28, the laser light L obliquely enters the optical coupler 209. This makes it possible to efficiently propagate the laser light L to the Si antenna 251 in the optical coupler 209. As a result, it is possible to further enhance optical coupling between the optical waveguide WG1 and the surface emitting laser.

### Modification Example C

In the embodiments described above and modification examples thereof, a gap may be provided at a location in contact with the Si antenna 251. For example, as illustrated in FIG. 29, in the PIC substrate 700A, both the interlayer insulating film 202 and the BOX layer 203 may have a gap 706 (e.g., an air gap). The gap 706 is provided at a location opposed to the Si antenna 251. Providing the gap 706 in such a manner makes it possible to make an oscillation angle from the Si antenna 251 about 1.5 times wider than that in a case where no gap is provided.

In the present modification example, the interlayer insulating film 202 may include a wall section 707 at a location in contact with the gap 706. In addition, in the present modification example, the BOX layer 203 may include a wall section 708 at a location in contact with the gap 706. The wall sections 707 and 708 each include, for example, a material (e.g., SiN) resistant to etchants suitable for etching of Si.

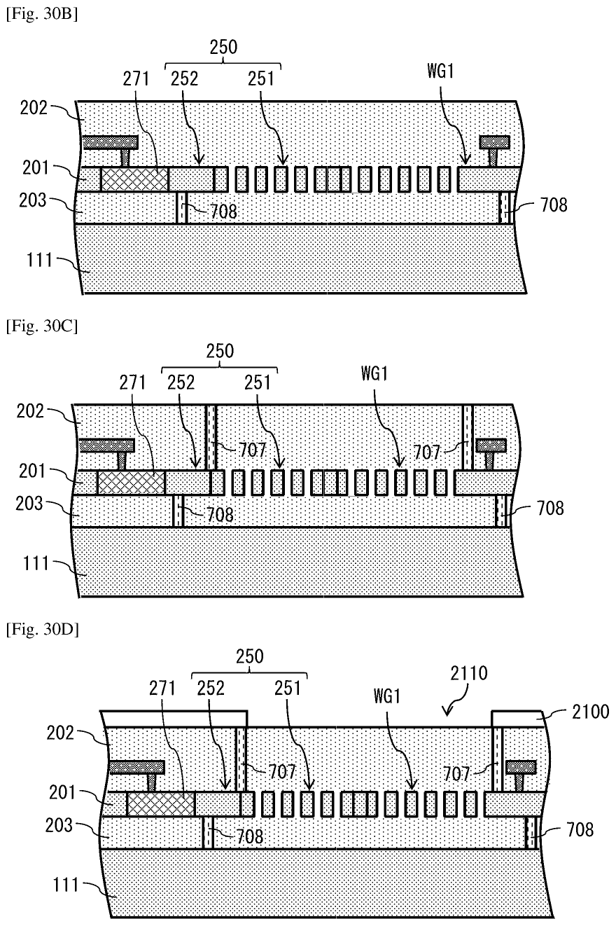

Next, description is given of a method of manufacturing a distance measuring device according to the present modification example. First, the SOI substrate 110 in which the wall section 707 is provided in the BOX layer 203 is prepared (FIG. 30A). Next, the optical waveguides WG1, WG2, and WG3, the splitter 230, the circulator 240, the Si antenna 251, the coupler 260, and portions (the Si terrace sections 71 and the p-type Si layers 72) of the Ge-PDs 271 and 272 are formed in the Si layer 201 of the SOI substrate 110 (FIG. 30A). Next, the interlayer insulating film 202 is formed on the SOI substrate 110 (FIG. 30B). Next, the wall section 707 is formed in the interlayer insulating film 202 (FIG. 30C).

Next, a resist layer 2100 having an opening 2110 at a location surrounded by the wall section 707 on the front surface of the interlayer insulating film 202 is formed (FIG. 30D). Next, the interlayer insulating film 202 and the BOX layer 203 are selectively etched with use of an etchant suitable for etching of Si. The gap 706 is thereby formed in both the interlayer insulating film 202 and the BOX layer 203. Thus, the distance measuring device according to the present modification example is manufactured.

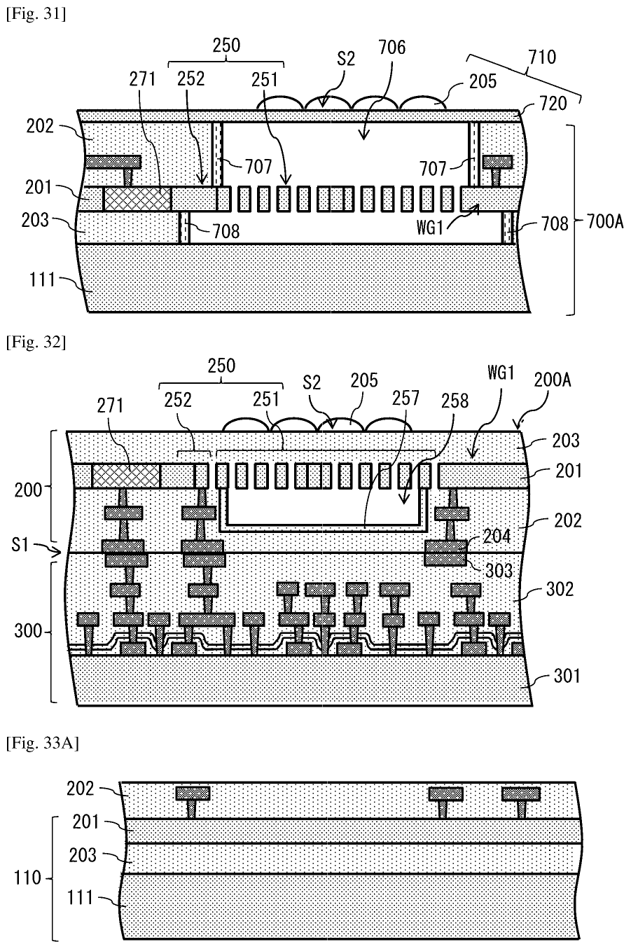

In the present modification example, for example, as illustrated in FIG. 31, a module lens 710 in which the lens 205 is stacked on a Si substrate 720 may be provided. On this occasion, the gap 706 may be sealed with the module lens 710. Accordingly, in a case where the module lens 710 is used, it is possible to dispose the lens 205 on the Si antenna 251 with the gap 706 interposed therebetween.

### Modification Example D

In the embodiments described above and modification examples thereof, a gap may be provided in only one of upper and lower regions in contact with the Si antenna 251. For example, as illustrated in FIG. 32, in the PIC substrate 200A, only the interlayer insulating film 202 may have a gap 258 (e.g., an air gap). The gap 258 is provided at location opposed to the Si antenna 251.

In the present modification example, the interlayer insulating film 202 may include a wall section 257 at a location in contact with the gap 258. The wall section 257 includes, for example, a material (e.g., SiN) resistant to etchants suitable for etching of Si and SiO₂.

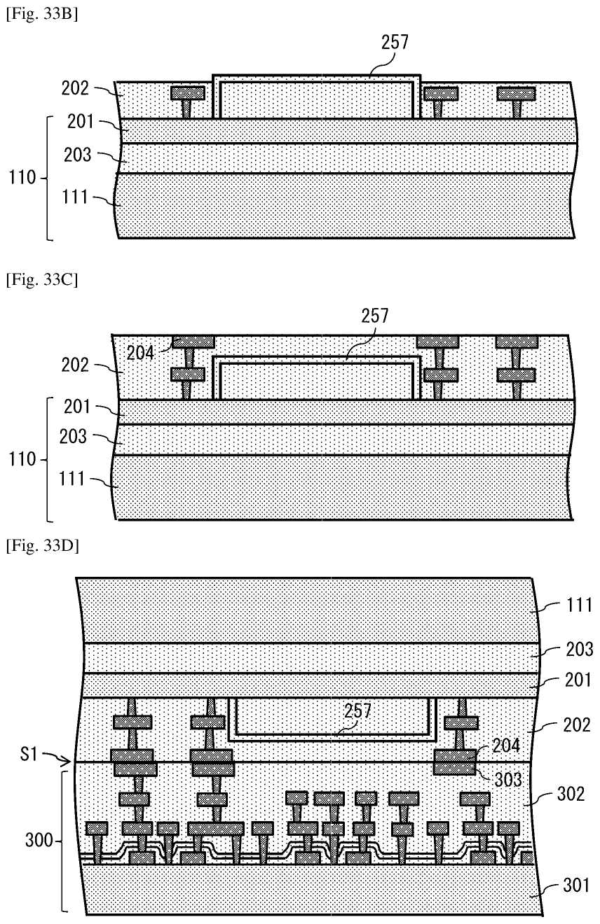

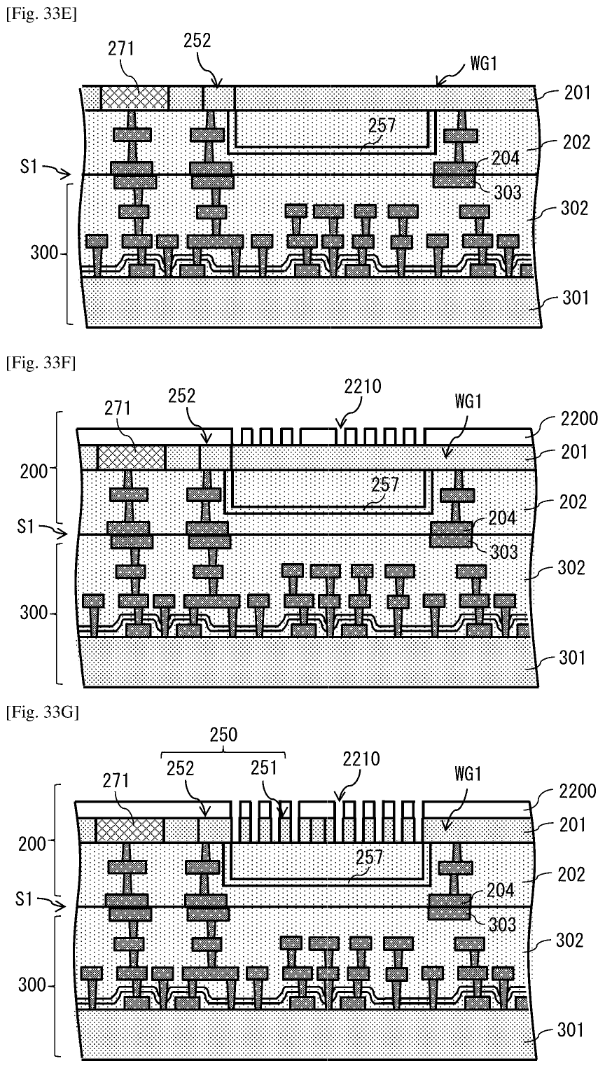

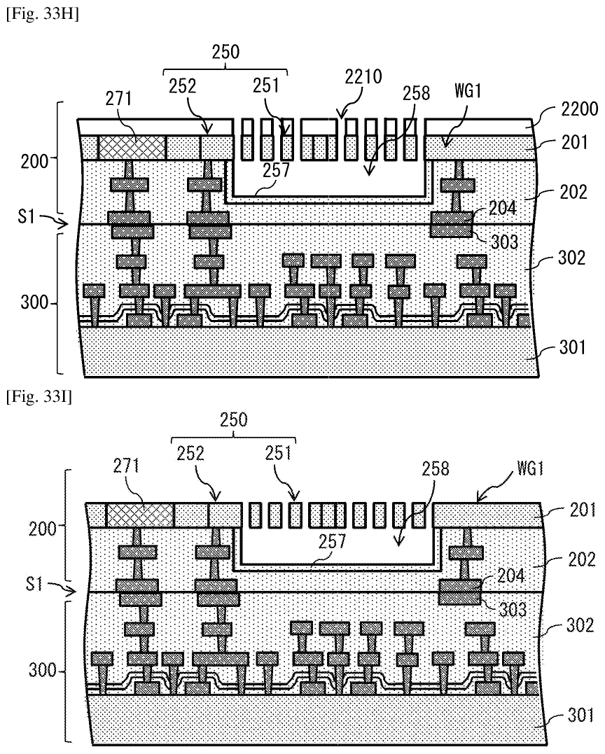

Next, description is given of a method of manufacturing a distance measuring device according to this modification example. First, the SOI substrate 110 is prepared. Next, the interlayer insulating film 202 is formed on the SOI substrate 110 (FIG. 33A). Next, after a groove section that penetrates through the interlayer insulating film 202 is formed, the wall section 257 is formed to fill in the groove section (FIG. 33B). Subsequently, the interlayer insulating film 202 is formed to embed the wall section 257 therein (FIG. 33C).

Next, the SOI substrate 110 and the lower die 300 are bonded to each other with the front surface of the interlayer insulating film 202 and the front surface of the interlayer insulating film 302 opposed to each other (FIG. 33D). Thus, the SOI substrate 110 and the lower die 300 are electrically coupled to each other. Next, the Si substrate 111 and the BOX layer 203 in the SOI substrate 110 are removed (FIG. 33E). Thus, the Si layer 201 is exposed. Next, the optical waveguides WG1, WG2, and WG3, the splitter 230, the circulator 240, the coupler 260, and portions (the Si terrace sections 71 and the p-type Si layers 72) of the Ge-PDs 271 and 272 are formed in the Si layer 201 of the SOI substrate 110 (FIG. 33E).

Next, a resist layer 2200 having an opening 2210 is formed on the front surface of the Si layer 201 (FIG. 33F). Next, the resist layer 2200 is used as a mask to selectively etch the Si layer 201 with use of an etchant suitable for etching of Si (FIG. 33G). The Si antenna 251 is thereby formed in the Si layer 201. Next, the interlayer insulating film 202 is selectively etched with use of an etchant suitable for etching of SiO₂ to form the gap 258 directly below the Si antenna 251 (FIG. 33H). Thereafter, the resist layer 2200 is removed (FIG. 33I). Thus, the distance measuring device according to the present modification example is manufactured.

In the present modification example, in the PIC substrate 200A, only the interlayer insulating film 202 has the gap 258. The gap 258 is provided at a location opposed to the Si antenna 251. Providing the gap 258 in such a manner makes it possible to make an oscillation angle from the Si antenna 251 about 1.5 times wider than that in a case where no gap is provided.

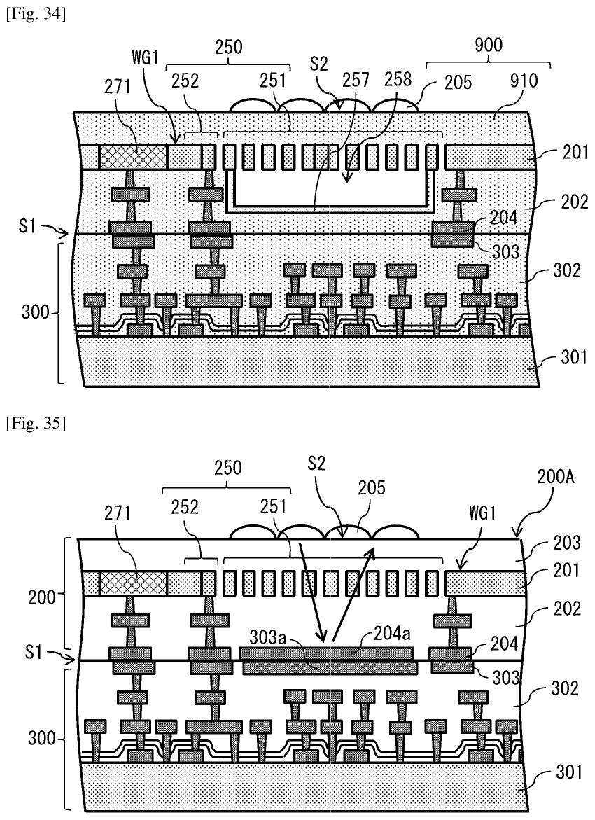

In the present modification example, for example, as illustrated in FIG. 34, a module lens 900 in which the lens 205 is stacked on a Si substrate 910 may be provided. On this occasion, the gap 258 may be sealed with the module lens 900. Accordingly, in a case where the module lens 900 is used, it is possible to dispose the lens 205 on the Si layer 201 with the gap 258 interposed therebetween.

### Modification Example E

In the embodiments described above and modification examples thereof, a reflection layer may be provided that reflects the reception signal Srx having passed through the Si antenna 251 to side of the Si antenna 251. For example, as illustrated in FIG. 35, in the PIC substrate 200A, a reflection layer 204a may be provided in the interlayer insulating film 202. The reflection layer 204a is provided at a position opposed to the Si antenna 251 in the interlayer insulating film 202. The reflection layer 204a reflects the return signal Srx, and cause thus-reflected light to enter the Si antenna 251. On this occasion, in the lower die 300, a wiring layer 303a joined to the reflection layer 204a is provided. The reflection layer 204a and the wiring layer 303a each include, for example, Cu. Thus, providing the reflection layer 204a makes it possible to expect an effect of enhancing quantum efficiency by reflection by the reflection layer 204a.

### Modification Example F

In the embodiments described above and modification examples thereof, a laser and a signal processing substrate may be coupled to each other by a bonding wire.

For example, as illustrated in FIG. 36, in the distance measuring device 100, a through hole 308 is provided that reaches a wiring layer 307 in the interlayer insulating film 302 of the lower die 300 from the bottom surface of the cutout section 206 of the PIC substrate 200A. Furthermore, a bonding wire 309 is provided that is coupled to a front surface of the wiring layer 307 exposed on a bottom surface of the through hole 308 and a front surface of an electrode 214 of the edge emitting layer 210. The wiring layer 307 and the electrode 214 each include, for example, gold (Au). The bonding wire 309 includes, for example, gold (Au). In such a case, it is possible to have a degree of freedom in a mounting place of the laser 210.

For example, as illustrated in FIG. 37, in the distance measuring device 100, a through hole 308 is provided that reaches the wiring layer 307 in the interlayer insulating film 302 of the lower die 300 from a bottom surface of a cutout section 203a of the PIC substrate 200A. Furthermore, the bonding wire 309 is provided that is coupled to the front surface of the wiring layer 307 exposed on the bottom surface of the through hole 308 and a front surface of an electrode 282 of the surface emitting laser 280. The cutout section 203a is provided to shorten a distance between the active layer 281 of the laser 280 and the optical coupler 209. The wiring layer 307 and the electrode 282 each include, for example, gold (Au). The bonding wire 309 includes, for example, gold (Au). In such a case, it is possible to have a degree of freedom in a mounting place of the laser 280.

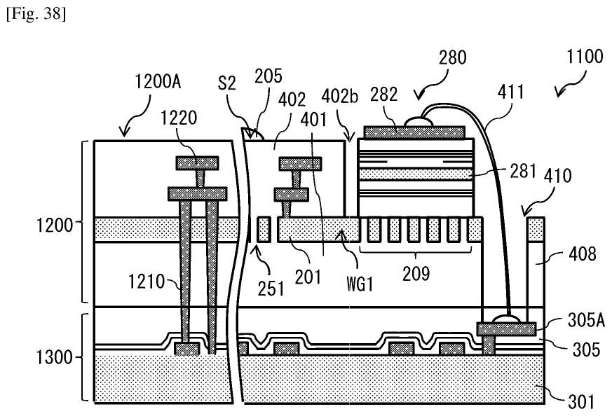

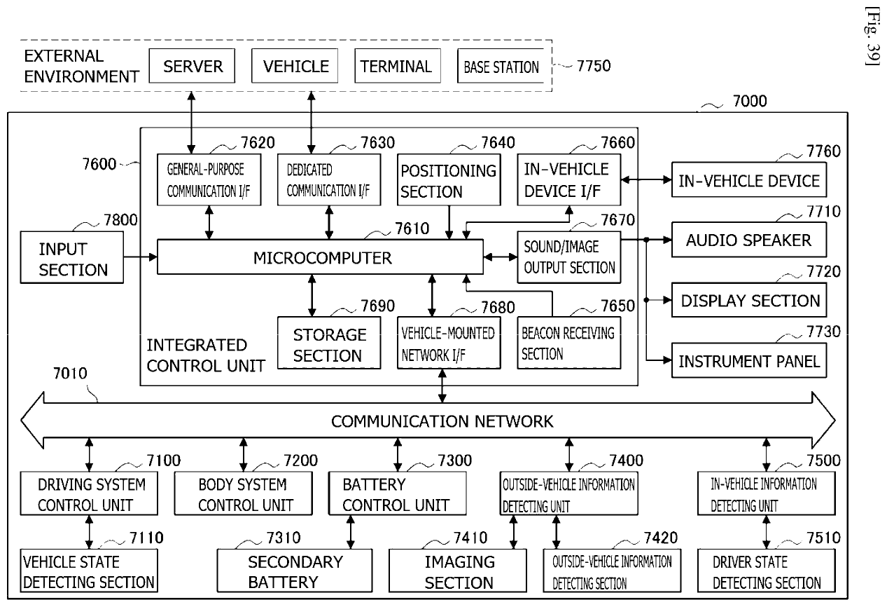

For example, as illustrated in FIG. 38, in the distance measuring device 1100, a through hole 410 is provided that reaches a wiring layer 305a in the insulating layer 305 of the lower layer 1300 from a bottom surface of a cutout section 402b of the PIC layer 1200A. Furthermore, a bonding wire 411 is provided that is coupled to a front surface of the wiring layer 305a exposed on a bottom surface of the through hole 410 and the front surface of the electrode 282 of the surface emitting laser 280. The cutout section 402b is provided to shorten a distance between the active layer 281 of the laser 280 and the optical coupler 209. The wiring layer 305a and the electrode 282 each include, for example, gold (Au). The bonding wire 411 includes, for example, gold (Au). In such a case, it is possible to have a degree of freedom in the mounting place of the laser 280.

### 8. Application Example

The technology according to the present disclosure is applicable to various products. For example, the technology according to the present disclosure may be achieved in the form of a device to be mounted to a mobile body of any kind such as an automobile, an electric vehicle, a hybrid electric vehicle, a motorcycle, a bicycle, a personal mobility, an airplane, a drone, a vessel, a robot, a construction machine, and an agricultural machine (tractor).

FIG. 39 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example depicted in FIG. 39, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of op-erations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 39 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

FIG. 40 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 40 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by super-imposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 39, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an elec-tromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infras-tructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electro-magnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 39, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 39 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

It is to be noted that it is possible to mount a computer program for implementing each function of the distance measuring devices described with reference to FIGS. 1 to 38 and the like on any control unit or the like. In addition, it is also possible to provide a computer-readable recording medium in which such a computer program is stored. The recording medium is, for example, a magnetic disk, an optical disk, a magneto-optical disk, a flash memory, or the like. In addition, the computer program described above may be distributed through a network, for example, without using a recording medium.

The vehicle control system 7000 described above is able to use any of the distance measuring devices described with reference to FIGS. 1 to 38 and the like, for example, as a light source steering section of an LIDAR as an environmental sensor. In addition, an optical computing unit using any of the distance measuring devices described with reference to FIGS. 1 to 38 and the like is able to perform image recognition in an imaging section. In a case where any of the distance measuring devices described with reference to FIGS. 1 to 38 and the like is used as a projection device having high efficiency and high luminance, it is possible to project a line or a character on the ground. Specifically, it is possible to display a line for a person outside a vehicle to recognize a position where the vehicle is to travel upon moving back the vehicle, or to display a pedestrian crossing with light upon giving way to a pedestrian.

In addition, at least some of components of the distance measuring devices described with reference to FIGS. 1 to 38 and the like may be implemented in a module (e.g., an integrated circuit module included in one die) for the integrated control unit 7600 illustrated in FIG. 39. Alternatively, the distance measuring devices described with reference to FIGS. 1 to 38 and the like may be implemented by a plurality of control units of the vehicle control system 7000 illustrated in FIG. 39.

Although the present disclosure has been described with reference to the embodiments and the modification examples thereof, the present disclosure is not limited to the embodiments and the like described above, and may be modified in a variety of ways. It is to be noted that the effects described herein are merely illustrative. The effects of the present disclosure are not limited to those described herein. The present disclosure may have effects other than those described herein.

In addition, for example, the present disclosure may also have the following config-urations.

(1)

A distance measuring device including:
a photonic integration circuit substrate including a first waveguide, a splitter, a second waveguide, and a signal generator that are provided in a common silicon layer, the first waveguide that transmits a chirp signal, the splitter that splits the chirp signal into a transmission signal and a reference signal, the second waveguide that transmits a return signal corresponding to a signal having a delayed phase in relation with the transmission signal, and the signal generator that generates a beat signal on the basis of the reference signal and the return signal; and
a signal processing substrate including a converter and a signal processor, the converter that performs analog-to-digital conversion of the beat signal, and the signal processor that processes the beat signal being digital generated by the converter, and
the photonic integration circuit substrate and the signal processing substrate being stacked on each other, and being electrically coupled to each other through a joining surface between the photonic integration circuit substrate and the signal processing substrate.
   (2)

The distance measuring device according to (1), in which a modulator and a silicon antenna are provided in the silicon layer, the modulator that generates the chirp signal, and the silicon antenna that outputs the transmission signal to outside, and receives the return signal from the outside.

(3)

The distance measuring device according to one or more of (1) to (2), further including a light source chip that is mounted on the photonic integration circuit substrate, and generates a light signal, in which
the signal processing substrate includes a controller that controls the light source chip, the modulator, and the silicon antenna,
the light source chip generates the light signal in accordance with control by the controller,
the modulator modulates the light signal in accordance with control by the controller to generate the chirp signal, and
the silicon antenna sweeps the transmission signal in a predetermined region of the outside in accordance with control by the controller.
   (4)

The distance measuring device according to one or more of (1) to (3), in which the photonic integration circuit substrate and the signal processing substrate are electrically coupled to each other by joining copper pads to each other, the copper pads being provided on a joining surface between the photonic integration circuit substrate and the signal processing substrate.

(5)

The distance measuring device according to one or more of (1) to (4), in which the photonic integration circuit substrate and the signal processing substrate are electrically coupled to each other through a through-hole via that penetrates through a joining surface between the photonic integration circuit substrate and the signal processing substrate.

(6)

The distance measuring device according to one or more of (1) to (5), in which the signal processing substrate has a chip shape smaller in size than the photonic integration circuit substrate, and is mounted on a front surface of the photonic integration circuit substrate.

(7)

The distance measuring device according to one or more of (1) to (6), in which the signal processing substrate further includes a first marker, and the photonic integration circuit substrate further includes a second marker at a position opposed to the first marker.

(8)

The distance measuring device according to one or more of (1) to (7), in which the light source chip includes an edge emitting laser, and is mounted on the photonic integration circuit substrate to set a light spot of the light source chip at a same height as the silicon layer, and the light source chip inputs the light signal to the modulator through an end surface of the first waveguide.

(9)

The distance measuring device according to one or more of (1) to (8), in which the light source chip and the photonic integration circuit substrate are electrically coupled to each other by joining copper pads to each other, the copper pads being provided between the light source chip and the photonic integration circuit substrate.

(10)

The distance measuring device according to one or more of (1) to (9), in which the light source chip and the photonic integration circuit substrate are electrically coupled to each other through a metal bump provided between the light source chip and the photonic integration circuit substrate.

(11)

The distance measuring device according to one or more of (1) to (10), in which in the photonic integration circuit substrate, a tapered waveguide section is provided, the tapered waveguide section having an end surface on a surface continuous with an end surface of the first waveguide.

(12)

The distance measuring device according to one or more of (1) to (11), in which the light source chip includes a laser that outputs the light signal in a stacking direction, and an optical coupler that optically couples the light source chip and the first waveguide to each other is provided in the silicon layer.

(13)

The distance measuring device according to one or more of (1) to (12), in which the light source chip includes a laser that outputs the light signal in a stacking direction, and in the photonic integration circuit substrate, an optical element that refracts the light signal is provided between the light source chip and the silicon layer, and an optical coupler that optically couples the light source chip and the first waveguide to each other with the optical element interposed therebetween is provided in the silicon layer.

(14)

The distance measuring device according to one or more of (1) to (13), in which the light source chip includes a laser that outputs the light signal in a direction obliquely intersecting with a stacking direction, and an optical coupler that optically couples the light source chip and the first waveguide to each other is provided in the silicon layer.

(15)

The distance measuring device according to one or more of (1) to (14), in which the photonic integration circuit substrate has a gap at a location in contact with the silicon antenna.

(16)

The distance measuring device according to one or more of (1) to (15), in which the photonic integration circuit substrate includes a first insulating layer and a second insulating layer between which the silicon layer is sandwiched, and one or both of the first insulating layer and the second insulating layer have the gap.

(17)

The distance measuring device according to one or more of (1) to (16), in which in the photonic integration circuit substrate, a reflection layer is provided at a location opposed to the silicon antenna, the reflection layer that reflects the return signal to cause reflected light to enter the silicon antenna.

(18) A distance measuring device, comprising:
a first substrate including:
a first optical waveguide configured to convey a chirp signal;
a splitter configured to split the chirp signal into a transmission signal and a reference signal; and
a coupler and detector block configured to output a beat signal based on the reference signal and a reflected signal; and
a second substrate stacked on the first substrate and including:
a converter configured to output a digital beat signal based on the beat signal; and
a controller configured to output an electronic control signal that controls generation of the chirp signal.
   (19) The distance measuring device of (18), wherein the first substrate further comprises:
a light source mounted on the first substrate and that generates light for modulation by a modulator to generate the chirp signal;
an antenna that transmits the chirp signal and that receives the reflected signal.
   (20) The distance measuring device of one or more (18) to (19), wherein the coupler and detector block includes:
an optical coupler that couples the reference signal and the reflected signal; and
at least one detector that detects output of the optical coupler to output the beat signal.
   (21) The distance measuring device of one or more (18) to (20), wherein the first substrate and the second substrate include one or more wiring layers that electrically connect the coupler and detector block to the converter.
   (22) The distance measuring device of one or more (18) to (21), wherein the one or more wiring layers includes a first plurality of pads of the first substrate bonded to a second plurality of pads of the second substrate.
   (23) The distance measuring device of one or more (18) to (22), wherein the one or more wiring layers includes one or more through hole vias that bond the first substrate to the second substrate.
   (24) The distance measuring device of one or more (18) to (23), wherein the light source comprises a vertical cavity surface emitting laser disposed over an optical coupler in the first substrate.
   (25) The distance measuring device of one or more (18) to (24), wherein the one or more through hole vias include a through hole via that penetrates through the first substrate.
   (26) The distance measuring device of one or more (18) to (25), wherein a footprint of the second substrate is smaller than a footprint of the first substrate.
   (27) The distance measuring device of one or more (18) to (26), wherein the second substrate further comprises a shallow trench isolation region below the antenna.
   (28) The distance measuring device of one or more (18) to (27), wherein the first substrate further comprises an air gap above or below the antenna.
   (29) The distance measuring device of one or more (18) to (28), wherein the first substrate further comprises an air gap above and below the antenna.
   (30) The distance measuring device of one or more (18) to (29), wherein at least one of the first substrate or the second substrate comprises a reflective layer below the antenna.
   (31) The distance measuring device of one or more (18) to (30), wherein the light source is electrically connected to the second substrate by a bonding wire.
   (32) The distance measuring device of one or more (18) to (31), further comprising a tapered optical waveguide located at an end of the first optical waveguide that receives the chirp signal.
   (33) A distance measuring device, comprising:
a first substrate comprising one or more optical circuits that output a transmission signal to an object and that receives a reflected signal from the object; and
a second substrate bonded to the first substrate and comprising one or more electronic circuits that control generation of the transmission signal and that process the reflected signal.
   (34) The distance measuring device of (33), wherein the one or more optical circuits comprises:
one or more waveguides;
a splitter that splits a chirp signal from a light source into a reference signal and the transmission signal;
an antenna that transmits the transmission signal and receives the reflected signal;
a coupler that couples the reference signal and the reflected signal; and
a detector that detects output of the coupler to output a beat signal.
   (35) The distance measuring device of one or more (33) to (34), wherein the one or more electronic circuits comprise:
a digital-to-analog converter (DAC) that drives the light source;
an analog-to-digital converter (ADC) that receives the beat signal from the detector;
and
a controller coupled to the DAC and the ADC.
   (36) The distance measuring device of one or more (33) to (35), wherein the first substrate and the second substrate include one or more wiring layers that electrically connect the DAC to the light source and that electrically connect the detector to the ADC.
   (37) A system, comprising:
an object; and
a distance measuring device that measures a distance to the object, the distance measuring device comprising:
a first substrate including:
a first optical waveguide configured to convey a chirp signal;
a splitter configured to split the chirp signal into a transmission signal and a reference signal; and
a coupler and detector block configured to output a beat signal based on the reference signal and a reflected signal; and
a second substrate stacked on the first substrate and including:
a converter configured to output a digital beat signal based on the beat signal; and
a controller configured to output an electronic control signal that controls generation of the chirp signal.

In a distance measuring device according to an embodiment of the present disclosure, in a PIC substrate, a first waveguide, a splitter, a second waveguide, and a signal generator are provided in a common silicon layer. In addition, a converter and a signal processor are provided in a signal processing substrate. Furthermore, the PIC substrate and the signal processing substrate are stacked on each other, and are electrically coupled to each other through a joining surface between the PIC substrate and the signal processing substrate. This allows for downsizing, as compared with a module in which a plurality of RF components is coupled through an optical fiber.

It should be understood by those skilled in the art that various modifications, combinations, sub-combinations, and alterations may occur depending on design re-quirements and other factors insofar as they are within the scope of the appended claims or the equivalents thereof.

### REFERENCE SIGNS LIST

71 Si terrace section
72 p-type Si layer
73 island-shaped i-type Ge layer
74 two-dimensionally grown i-type Ge layer
75 n-type Ge layer
76 n-side electrode
77 p-side electrode
100, 500, 600, 1100 distance measuring device
110 SOI substrate
111 Si substrate
111a opening
200, 400 upper die
200A, 400A, 700A PIC substrate
201 Si layer
202 interlayer insulating film
203 BOX layer
204, 207 coupling pad
204a reflection layer
205 lens
206 cutout section
208 optical waveguide section
209 optical coupler
210 laser
211 active layer
212 bump
213 solder
215 Cu electrode
220 modulator
230 splitter
240 circulator
250 antenna
251 Si antenna
252 heater
253, 254, 255 optical switch
258 gap
257 wall section
260 coupler
261, 262 optical waveguide
270 detector
271, 272 Ge-PD
273 transimpedance amplifier
280 laser
281 active layer
290 prism
300, 700 lower die
301 Si substrate
302 interlayer insulating film
303 coupling pad
304 marker
305 insulating layer
306 light-shielding layer
310 controller
320 DAC
330 ADC
340 FFT
401 insulating layer
402 interlayer insulating film
403, 407 through-hole via
404 wiring layer
405, 409 light-shielding section
406 cutout section
408 coupling pad
701 cutout section
702 coupling pad
703 marker
704 wiring layer
705 Ge-PD
706 gap
707, 708 wall section
709 groove section
710 module lens
720 Si substrate
800 upper chip
900 module lens
910 Si substrate
1200 upper layer
1200A PIC layer
1210, 1230 via
1220 wiring layer
1240 STI section
1300 lower layer
2100, 2200 resist layer
2110, 2210 opening
S1 joining surface
S2 entrance/exit surface
S3, S4 front surface
Sbt beat signal
Stx, Stx1, Stx2 transmission signal
Srx reception signal
TG target
WG1, WG2, WG3 optical waveguide

What is claimed is:

1. A distance measuring device comprising:
a photonic integration circuit substrate including a first waveguide, a splitter, a second waveguide, and a signal generator that are provided in a common silicon layer, the first waveguide that transmits a chirp signal, the splitter that splits the chirp signal into a transmission signal and a reference signal, the second waveguide that transmits a return signal corresponding to a signal having a delayed phase in relation with the transmission signal, and the signal generator that generates a beat signal on a basis of the reference signal and the return signal; and
a signal processing substrate including a converter and a signal processor, the converter that performs analog-to-digital conversion of the beat signal, and the signal processor that processes the beat signal being digital generated by the converter, and
the photonic integration circuit substrate and the signal processing substrate being stacked on each other, and being electrically coupled to each other through a joining surface between the photonic integration circuit substrate and the signal processing substrate.

2. The distance measuring device according to claim 1, wherein a modulator and a silicon antenna are provided in the silicon layer, the modulator that generates the chirp signal, and the silicon antenna that outputs the transmission signal to outside, and receives the return signal from the outside.

3. The distance measuring device according to claim 2, further comprising a light source chip that is mounted on the photonic integration circuit substrate, and generates a light signal, wherein
the signal processing substrate includes a controller that controls the light source chip, the modulator, and the silicon antenna,
the light source chip generates the light signal in accordance with control by the controller,
the modulator modulates the light signal in accordance with control by the controller to generate the chirp signal, and
the silicon antenna sweeps the transmission signal in a predetermined region of the outside in accordance with control by the controller.

4. The distance measuring device according to claim 1, wherein the photonic integration circuit substrate and the signal processing substrate are electrically coupled to each other by joining copper pads to each other, the copper pads being provided on a joining surface between the photonic integration circuit substrate and the signal processing substrate.

5. The distance measuring device according to claim 1, wherein the photonic integration circuit substrate and the signal processing substrate are electrically coupled to each other through a through-hole via that penetrates through a joining surface between the photonic integration circuit substrate and the signal processing substrate.

6. The distance measuring device according to claim 1, wherein the signal processing substrate has a chip shape smaller in size than the photonic integration circuit substrate, and is mounted on a front surface of the photonic integration circuit substrate.

7. The distance measuring device according to claim 6, wherein
the signal processing substrate further includes a first marker, and
the photonic integration circuit substrate further includes a second marker at a position opposed to the first marker.

8. The distance measuring device according to claim 3, wherein
the light source chip comprises an edge emitting laser, and is mounted on the photonic integration circuit substrate to set a light spot of the light source chip at a same height as the silicon layer, and
the light source chip inputs the light signal to the modulator through an end surface of the first waveguide.

9. The distance measuring device according to claim 8, wherein the light source chip and the photonic integration circuit substrate are electrically coupled to each other by joining copper pads to each other, the copper pads being provided between the light source chip and the photonic integration circuit substrate.

10. The distance measuring device according to claim 8, wherein the light source chip and the photonic integration circuit substrate are electrically coupled to each other through a metal bump provided between the light source chip and the photonic integration circuit substrate.

11. The distance measuring device according to claim 8, wherein in the photonic integration circuit substrate, a tapered waveguide section is provided, the tapered waveguide section having an end surface on a surface continuous with an end surface of the first waveguide.

12. The distance measuring device according to claim 3, wherein
the light source chip comprises a laser that outputs the light signal in a stacking direction, and
an optical coupler that optically couples the light source chip and the first waveguide to each other is provided in the silicon layer.

13. The distance measuring device according to claim 3, wherein
the light source chip comprises a laser that outputs the light signal in a stacking direction, and
in the photonic integration circuit substrate, an optical element that refracts the light signal is provided between the light source chip and the silicon layer, and an optical coupler that optically couples the light source chip and the first waveguide to each other with the optical element interposed therebetween is provided in the silicon layer.

14. The distance measuring device according to claim 3, wherein
the light source chip comprises a laser that outputs the light signal in a direction obliquely intersecting with a stacking direction, and
an optical coupler that optically couples the light source chip and the first waveguide to each other is provided in the silicon layer.

15. The distance measuring device according to claim 2, wherein the photonic integration circuit substrate has a gap at a location in contact with the silicon antenna.

16. The distance measuring device according to claim 15, wherein
the photonic integration circuit substrate includes a first insulating layer and a second insulating layer between which the silicon layer is sandwiched, and one or both of the first insulating layer and the second insulating layer have the gap.

17. The distance measuring device according to claim 2, wherein in the photonic integration circuit substrate, a reflection layer is provided at a location opposed to the silicon antenna, the reflection layer that reflects the return signal to cause reflected light to enter the silicon antenna.
